(19) United States
(12) Patent Application Publication
(10) Pub. No.: US 2025/0372511 A1
(43) Pub. Date: Dec. 4, 2025

(54) SEMICONDUCTOR DEVICE AND VEHICLE

(71) Applicant: Rohm Co., Ltd., Kyoto-shi (JP)

(72) Inventor: Hidetoshi ABE, Kyoto-shi (JP)

(21) Appl. No.: 19/298,926

(22) Filed: Aug. 13, 2025

Related U.S. Application Data
(63) Continuation of application No. PCT/JP2024/002755, filed on Jan. 30, 2024.

(30) Foreign Application Priority Data
Feb. 20, 2023 (JP) 2023-024455

(51) Int. Cl. H01L 23/528; H01L 23/00; H01L 23/31; H01L 23/532; H01L 25/07; H10D 80/20

(52) U.S. Cl. CPC H01L 23/528; H01L 23/3121; H01L 23/53228; H01L 24/05; H01L 25/072; H01L 2224/05567; H10D 80/251

(57) ABSTRACT

A semiconductor device includes a conductive layer, a first semiconductor element having a first gate electrode, a second semiconductor element having a second gate electrode, and a first signal terminal electrically connected to the first gate electrode and the second gate electrode. The first signal terminal has a first contact point. Let L1 denote a length of a straight line connecting a first center of the first gate electrode and the first contact point. Let L2 denote a length of a straight line connecting a second center of the second gate electrode and the first contact point. Let R1 denote a first conductive-path length from the first center to the first contact point. Let R2 denote a second conductive-path length from the second center to the first contact point. Then, R2/R1 is closer to 1 than L2/L1 is.

### TECHNICAL FIELD

The present disclosure relates to a semiconductor device and a vehicle equipped with the semiconductor device.

### BACKGROUND ART

Semiconductor devices featuring switching elements, such as MOSFETs and IGBTs, are conventionally known. To ensure the current handling capacity of such a semiconductor device, the switching elements are connected in parallel, as disclosed in JP-A-2016-225493. The semiconductor device of JP-A-2016-225493 includes a plurality of first semiconductor elements, a plurality of first connection wirings, a wiring layer, and a signal terminal. The first semiconductor elements are switching elements. Each first semiconductor element switches on and off based on the drive signal inputted to the gate electrode. The first semiconductor elements are connected in parallel. The first connection wirings may be wires connecting the gate electrode of each first semiconductor element and the wiring layer. The wiring layer is connected to the signal terminal. The signal terminal is connected to the gate electrodes of the first semiconductor elements via the wiring layer and the first connection wirings. The signal terminal supplies a gate signal to the gate electrodes of the first semiconductor elements to drive the first semiconductor elements.

A semiconductor device including a plurality of semiconductor elements connected in parallel as in the semiconductor device of JP-A-2016-225493 is prone to resonance during switching (on and off) of the semiconductor elements. The resonance can induce oscillations in the drive signal of the semiconductor elements. Depending on the magnitude of these oscillations, malfunction or damage of the semiconductor elements may occur.

### BRIEF DESCRIPTION OF THE DRAWINGS

FIG. 1 is a plan view of a semiconductor device according to a first embodiment of the present disclosure.

FIG. 2 is a plan view corresponding to FIG. 1, with a sealing resin shown as transparent.

FIG. 3 is a bottom view of the semiconductor device shown in FIG. 1.

FIG. 4 is a right-side view of the semiconductor device shown in FIG. 1.

FIG. 5 is a sectional view taken along line V-V in FIG. 2.

FIG. 6 is a sectional view taken along line VI-VI in FIG. 2.

FIG. 7 is a sectional view taken along line VII-VII in FIG. 2.

FIG. 8A is a partially enlarged view of FIG. 5, showing a portion around a first semiconductor element.

FIG. 8B is a partially enlarged view of FIG. 5, showing a portion around a second semiconductor element.

FIG. 9 is a partially enlarged sectional view of FIG. 2.

FIG. 10 is a sectional view taken along line X-X in FIG. 9.

FIG. 11 is a partially enlarged sectional view of a semiconductor device according to a first variation of the first embodiment of the present disclosure.

FIG. 12 is a partially enlarged sectional view of a semiconductor device according to a second variation of the first embodiment of the present disclosure.

FIG. 13 is a schematic diagram of a vehicle equipped with the semiconductor device shown in FIG. 1.

FIG. 14 is a plan view of a semiconductor device according to a second embodiment of the present disclosure, with a sealing resin shown as transparent.

FIG. 15 is a sectional view taken along line XV-XV in FIG. 14.

FIG. 16 is a sectional view taken along line XVI-XVI in FIG. 14.

FIG. 17 is a partially enlarged sectional view of FIG. 14.

FIG. 18 is a sectional view taken along line XVIII-XVIII in FIG. 17.

FIG. 19 is a plan view of a semiconductor device according to a third embodiment of the present disclosure, with a sealing resin shown as transparent.

FIG. 20 is a sectional view taken along line XX-XX in FIG. 19.

FIG. 21 is a sectional view taken along line XXI-XXI in FIG. 19.

FIG. 22 is a partially enlarged sectional view of FIG. 19.

FIG. 23 is a sectional view taken along line XXIII-XXIII in FIG. 22.

FIG. 24 is a plan view of a semiconductor device according to a fourth embodiment of the present disclosure, with a sealing resin shown as transparent.

FIG. 25 is a sectional view taken along line XXV-XXV in FIG. 24.

### DETAILED DESCRIPTION OF EMBODIMENTS

The following describes embodiments of the present disclosure, with reference to the accompanying drawings.

### First Embodiment

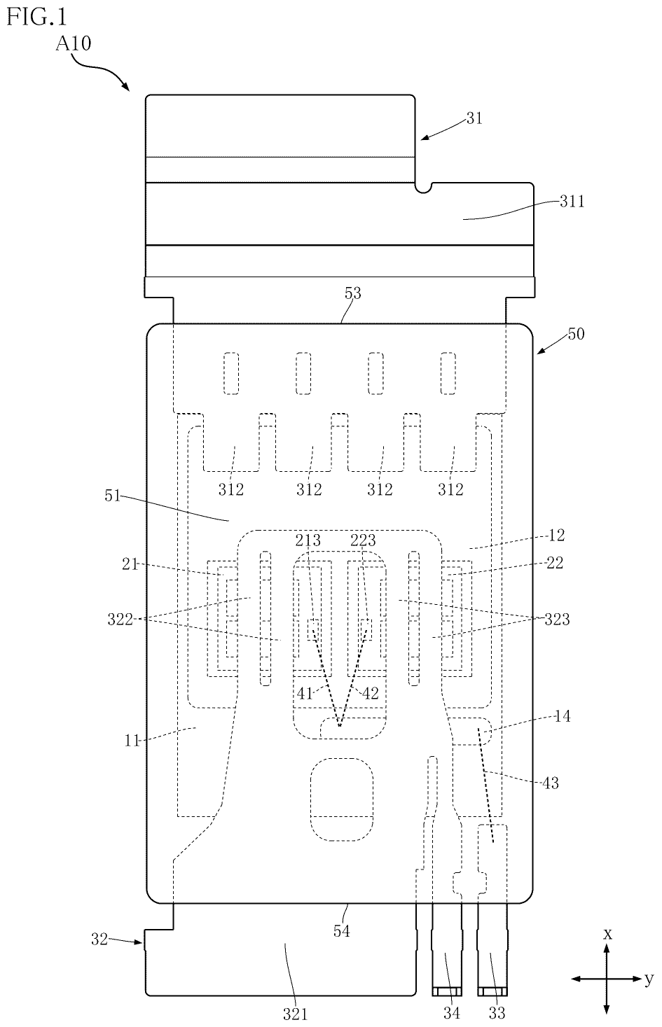

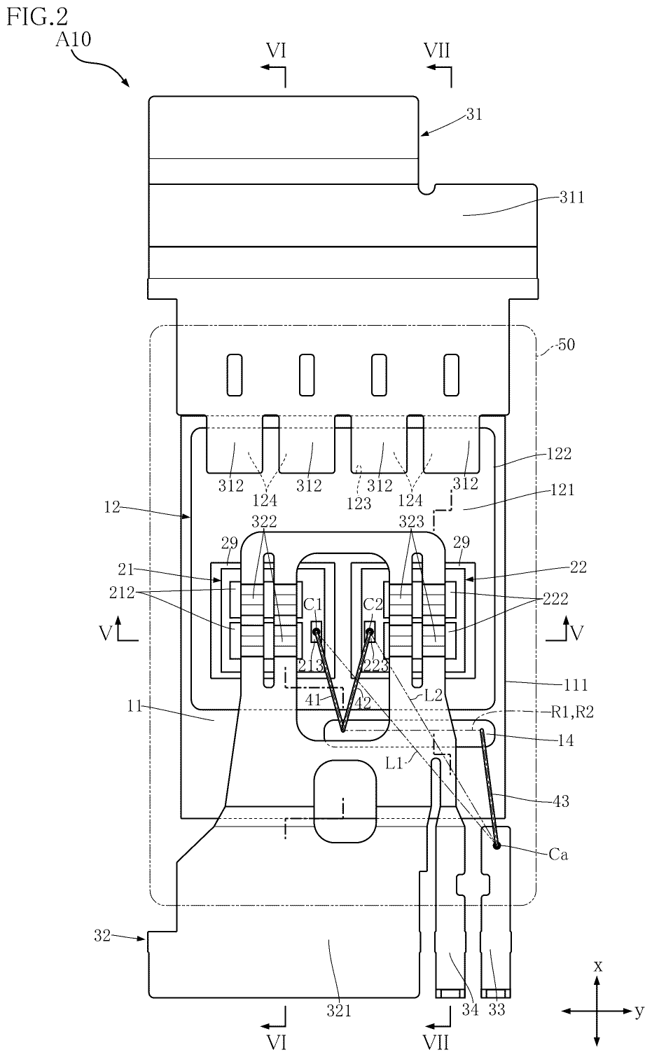

With reference to FIGS. 1 to 10, the following describes a semiconductor device A10 according to a first embodiment of the present disclosure. The semiconductor device A10 is typically used for a power conversion circuit, such an inverter. The semiconductor device A10 includes an insulating layer 11, a conductive layer 12, a heat dissipation layer 13, a first wiring layer 14, a first semiconductor element 21, a second semiconductor element 22, a first terminal 31, a second terminal 32, a first signal terminal 33, a second signal terminal 34, a bonding layer 39, and a sealing resin 50. The semiconductor device A10 additionally includes a first conductive member 41, a second conductive member 42, and a third conductive member 43. For convenience, FIG. 2 shows the sealing resin 50 as transparent. The outline of the sealing resin 50 is indicated by imaginary lines (dash-double-dot lines) in FIG. 2.

For convenience, the description of the semiconductor device A10 refers to three mutually perpendicular directions. For example, the direction of the normal to a later-described mounting surface 121 of the conductive layer 12 is referred to as a first direction z. A direction perpendicular to the first direction z is referred to as a second direction x. The direction perpendicular to both the first direction z and the second direction x is referred to as a third direction y.

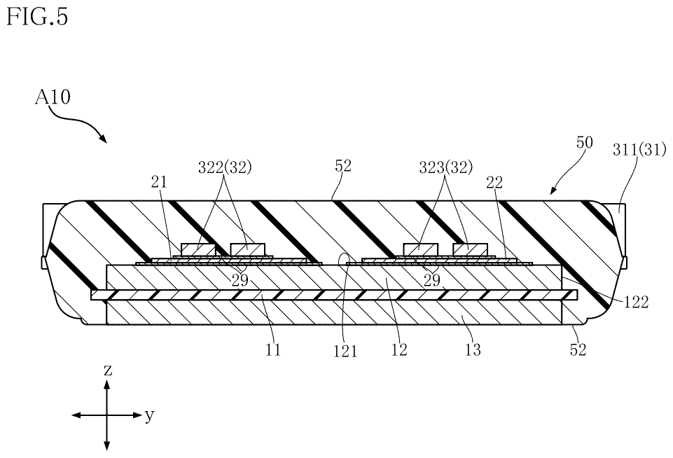

As shown in FIG. 5, the sealing resin 50 covers the first semiconductor element 21 and the second semiconductor element 22. The sealing resin 50 is an insulator. The sealing resin 50 is made of a material, including a black epoxy resin, for example.

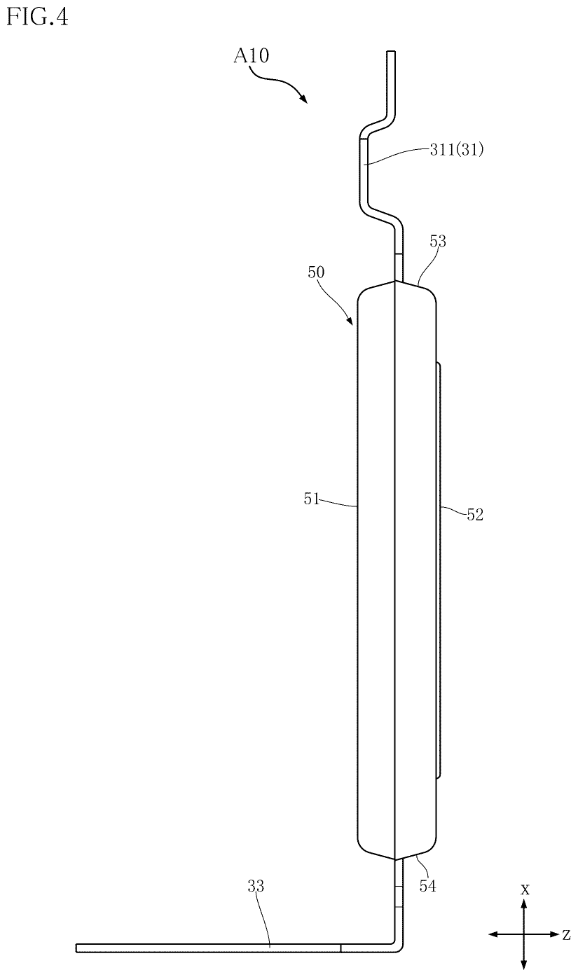

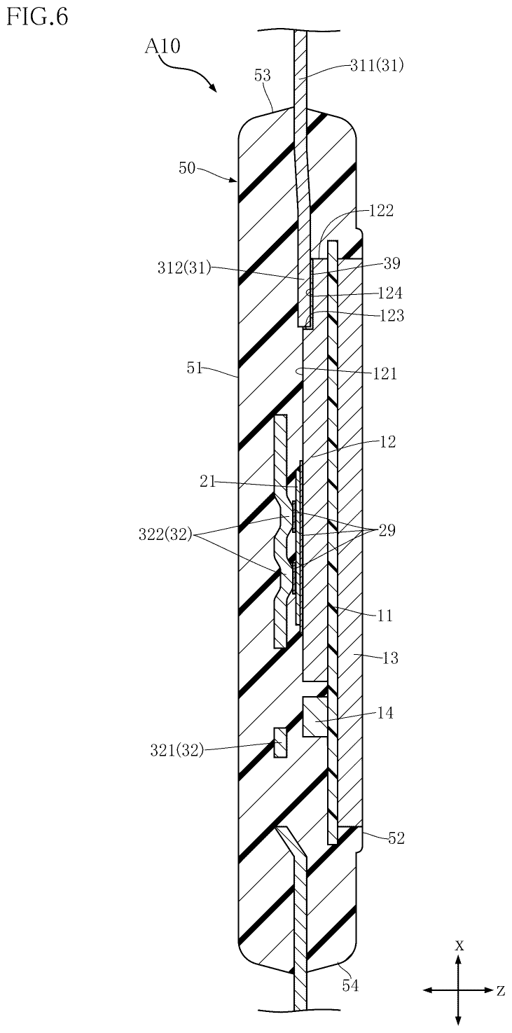

As shown in FIG. 4, the sealing resin 50 has a top surface 51, a bottom surface 52, a first side surface 53, and a second side surface 54. As shown in FIGS. 5 and 6, the top surface 51 faces the same side as the later-described mounting surface 121 of the conductive layer 12 in the first direction z. The bottom surface 52 faces away from the top surface 51 in the first direction z.

As shown in FIGS. 1, 3, and 4, the first side surface 53 and the second side surface 54 face away from each other in the second direction x. The first side surface 53 and the second side surface 54 are each connected to the top surface 51 and the bottom surface 52.

As shown in FIGS. 5 and 6, the insulating layer 11 is covered with the sealing resin 50. The insulating layer 11 is made of a material with a relatively high thermal conductivity. For example, the insulating layer 11 is made of a ceramic material containing either silicon nitride (Si₃N₄) or aluminum nitride (AlN). In another example, the insulating layer 11 may be made of a material, including resin.

As shown in FIGS. 5 and 6, the conductive layer 12 is bonded to one side of the insulating layer 11 in the first direction z. The conductive layer 12 is where the first semiconductor element 21 and the second semiconductor element 22 are mounted. As viewed in the first direction z, the conductive layer 12 is enclosed within the periphery 111 of the insulating layer 11. The conductive layer 12 is covered with the sealing resin 50. The conductive layer 12 contains copper (Cu). The dimension of the conductive layer 12 in the first direction z is larger than the dimension of the insulating layer 11 in the first direction z.

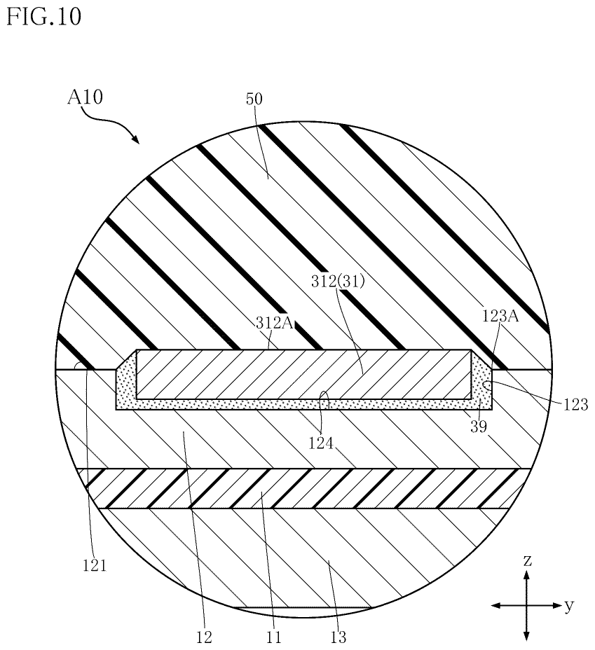

As shown in FIGS. 2 and 5, the conductive layer 12 has the mounting surface 121, the end surface 122, and a plurality of peripheral surfaces 123. The mounting surface 121 faces one side in the first direction z. The first semiconductor element 21 and the second semiconductor element 22 face in a direction of the mounting surface 121. The end surface 122 faces in a direction perpendicular to the first direction z. The end surface 122 is connected to the mounting surface 121. Each peripheral surface 123 faces in a direction perpendicular to the first direction z and is located inward of the conductive layer 12 from the end surface 122 as viewed in the first direction z. The peripheral surfaces 123 are next to each other in the third direction y. As shown in FIG. 10, each peripheral surface 123 has an upper edge 123A. The upper edge 123A is a boundary between the peripheral surface 123 and the mounting surface 121.

As shown in FIGS. 6 and 10, the conductive layer 12 is provided with a plurality of engagement portions 124. Each engagement portion 124 is defined by a peripheral surface 123. In the semiconductor device A10, each engagement portion 124 is a recess that is recessed from the mounting surface 121.

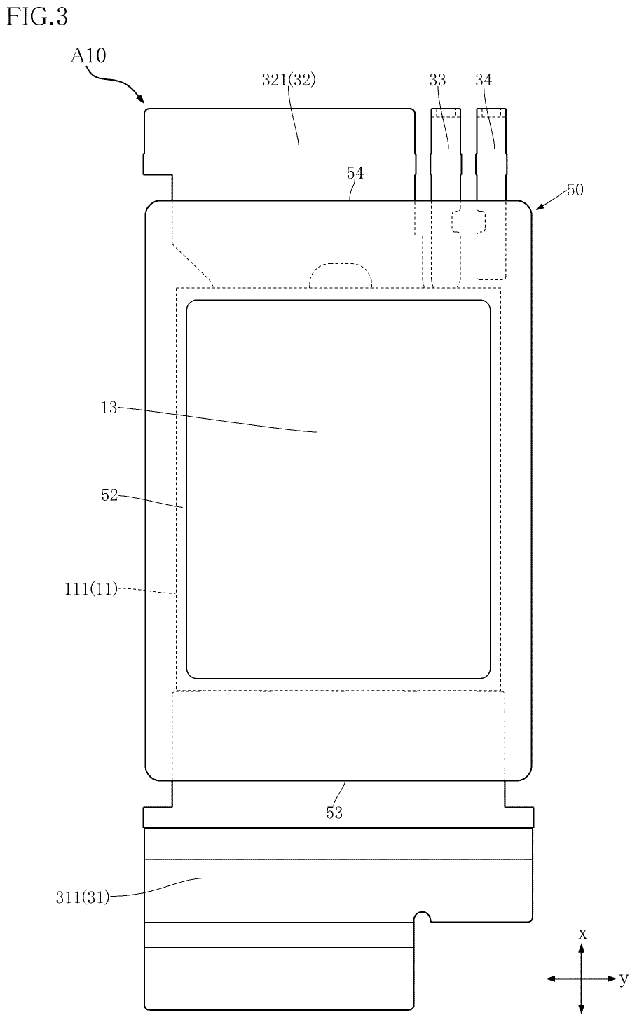

As shown in FIGS. 5 and 6, the heat dissipation layer 13 is located on the opposite side of the insulating layer 11 from the conductive layer 12 and is bonded to the insulating layer 11. As viewed in the first direction z, the heat dissipation layer 13 is enclosed within the periphery 111 of the insulating layer 11, overlapping with the conductive layer 12. As shown in FIG. 3, the heat dissipation layer 13 is exposed to the outside from the bottom surface 52 of the sealing resin 50. The heat dissipation layer 13 contains copper. In the semiconductor device A10, the dimension of the heat dissipation layer 13 in the first direction z is larger than the dimension of the insulating layer 11 in the first direction z, and is equal to the dimension of the conductive layer 12 in the first direction z. Alternatively, the dimension of the heat dissipation layer 13 in the first direction z relative to the dimensions of the insulating layer 11 and the conductive layer 12 in the first direction z may differ from the example in a variety of ways.

As shown in FIGS. 2, 6, and 7, the first wiring layer 14 is located on the same side as the conductive layer 12 with respect to the insulating layer 11 and is bonded to the insulating layer 11. The first wiring layer 14 is located next to the conductive layer 12 in the second direction x. The first wiring layer 14 extends in the third direction y. As viewed in the first direction z, the first wiring layer 14 is enclosed within the periphery 111 of the insulating layer 11. The first wiring layer 14 is covered with the sealing resin 50. The first wiring layer 14 contains copper. The dimension of the first wiring layer 14 in the first direction z is larger than the dimension of the insulating layer 11 in the first direction z.

As shown in FIGS. 5 and 6, the first semiconductor element 21 is bonded to the mounting surface 121 of the conductive layer 12. The first semiconductor element 21 is a metal-oxide-semiconductor field-effect transistor (MOSFET), for example. In other examples, the first semiconductor element 21 may be a field effect transistor, such as metal-insulator-semiconductor field-effect transistor (MISFET), or a bipolar transistor, such as an insulated gate bipolar transistor (IGBT). In the description of the semiconductor device A10 below, the first semiconductor element 21 is an n-channel vertical MOSFET. The first semiconductor element 21 includes a compound semiconductor substrate. The compound semiconductor substrate contains silicon carbide (SiC) in its composition.

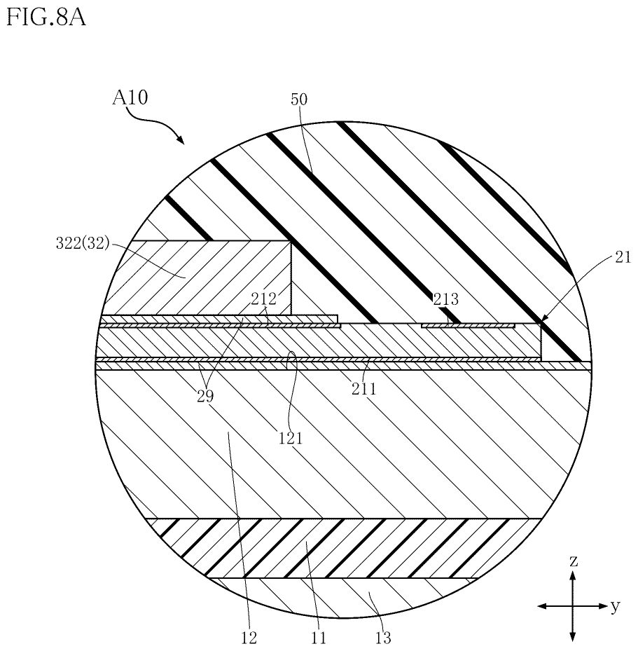

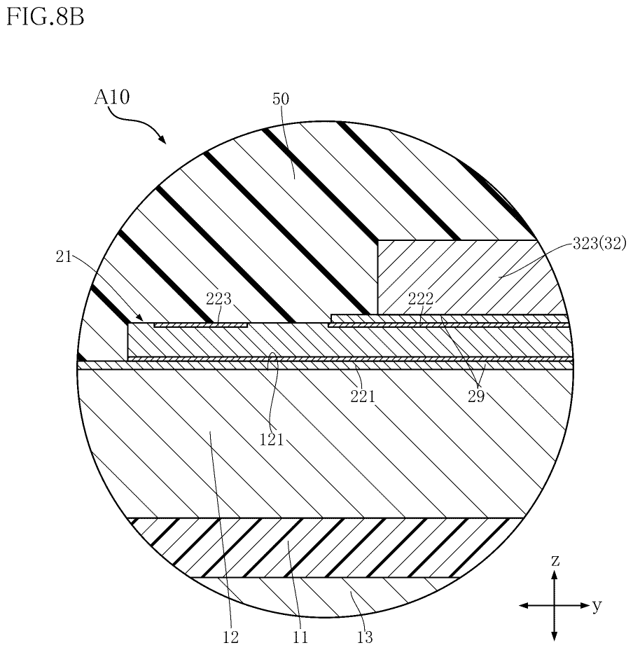

As shown in FIG. 8A, the first semiconductor element 21 includes a first electrode 211, two second electrodes 212, and a first gate electrode 213.

As shown in FIG. 8A, the first electrode 211 is located on one side in the first direction z. The first electrode 211 faces in the direction of the mounting surface 121 of the conductive layer 12. The first electrode 211 is electrically bonded to the mounting surface 121 via a conductive bonding layer 29. This electrically connects the first electrode 211 to the conductive layer 12. The conductive bonding layer 29 is solder, for example. In other examples, the conductive bonding layer 29 may be sintered metal, such as silver. The first electrode 211 is where the electric current corresponding to the power to be modulated by the first semiconductor element 21 flows. In short, the first electrode 211 is the drain of the first semiconductor element 21.

As shown in FIG. 8A, the two second electrodes 212 are disposed on the opposite side from the first electrode 211 in the first direction z. As shown in FIG. 2, the two second electrodes 212 are spaced apart from each other in the second direction x. Each of the two second electrodes 212 is where the electric current corresponding to the power modulated by the first semiconductor element 21 flows. In short, the two second electrodes 212 are the source of the first semiconductor element 21.

As shown in FIGS. 2 and 8A, the first gate electrode 213 is located on the same side as the two second electrodes 212 in the first direction z. The first gate electrode 213 is where the gate voltage for controlling the first semiconductor element 21 is applied. The first gate electrode 213 is electrically connected to the first wiring layer 14. As shown in FIG. 2, the first gate electrode 213 is smaller in area than each second electrode 212 as viewed in the first direction z. As viewed in the first direction z, the first gate electrode 213 is rectangular. As viewed in the first direction z, the first gate electrode 213 has a first center C1. The first center C1 is the intersection point of the diagonals of the first gate electrode 213.

As shown in FIG. 5, the second semiconductor element 22 is bonded to the mounting surface 121 of the conductive layer 12. The second semiconductor element 22 is of the same type as the first semiconductor element 21. Thus, the second semiconductor element 22 is also an n-channel vertical MOSFET. The second semiconductor element 22 is located next to the first semiconductor element 21 in the third direction y.

As shown in FIG. 8B, the second semiconductor element 22 includes a third electrode 221, two fourth electrodes 222, and a second gate electrode 223.

As shown in FIG. 8B, the third electrode 221 is located on one side in the first direction z. The third electrode 221 faces in the direction of the mounting surface 121 of the conductive layer 12. The third electrode 221 is electrically bonded to the mounting surface 121 via a conductive bonding layer 29. This electrically connects the third electrode 221 to the conductive layer 12. The third electrode 221 is where the electric current corresponding to the power to be modulated by the second semiconductor element 22 flows. In short, the third electrode 221 is the drain of the second semiconductor element 22.

As shown in FIG. 8B, the two fourth electrodes 222 are disposed on the opposite side from the third electrode 221 in the first direction z. As shown in FIG. 2, the two fourth electrodes 222 are spaced apart from each other in the second direction x. Each of the two fourth electrodes 222 is where the electric current corresponding to the power modulated by the second semiconductor element 22 flows. In short, the two fourth electrodes 222 are the source of the second semiconductor element 22.

As shown in FIGS. 2 and 8B, the second gate electrode 223 is located on the same side as the two fourth electrodes 222 in the first direction z. The second gate electrode 223 is where the gate voltage for controlling the second semiconductor element 22 is applied. The second gate electrode 223 is electrically connected to the first wiring layer 14. As shown in FIG. 2, the second gate electrode 223 is smaller in area than each fourth electrode 222 as viewed in the first direction z. As viewed in the first direction z, the second gate electrode 223 is rectangular. As viewed in the first direction z, the second gate electrode 223 has a second center C2. The second center C2 is the intersection point of the diagonals of the second gate electrode 223.

As shown in FIG. 2, the first terminal 31 is located on one side in the second direction x from the first semiconductor element 21 and the second semiconductor element 22. The first terminal 31 is electrically connected to the first electrode 211 of the first semiconductor element 21 and the third electrode 221 of the second semiconductor element 22. Thus, the first terminal 31 is the drain terminal of the semiconductor device A10. The first terminal 31 contains copper.

As shown in FIGS. 2 and 6, the first terminal 31 has a base portion 311 and a plurality of bonding portions 312. The base portion 311 is spaced apart from the mounting surface 121 of the conductive layer 12 as viewed in the first direction z. As shown in FIG. 1, the base portion 311 includes a portion covered with the sealing resin 50 and a portion exposed to the outside from the first side surface 53 of the sealing resin 50. As viewed in first direction z, the bonding portions 312 extend from the base portion 311 in the second direction x toward the first semiconductor element 21 and the second semiconductor element 22. The bonding portions 312 are next to each other in the third direction y. The bonding portions 312 are covered with the sealing resin 50. As viewed in the first direction z, the bonding portions 312 overlap with the respective engagement portions 124 of the conductive layer 12.

As shown in FIG. 10, the bonding layer 39 electrically bonds each engagement portion 124 of the conductive layer 12 and a corresponding bonding portion 312 of the first terminal 31. This electrically connects the first terminal 31 to the first electrode 211 of the first semiconductor element 21 and the third electrode 221 of the second semiconductor element 22. The bonding layer 39 is solder, for example.

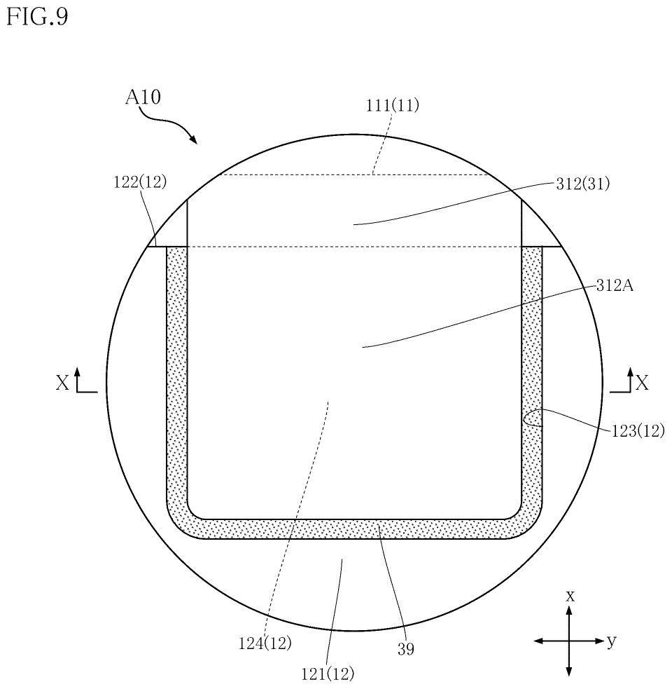

As shown in FIG. 10, at least a portion of each bonding portion 312 of the first terminal 31 is accommodated in the corresponding engagement portion 124 of the conductive layer 12. The bonding layer 39 is in contact with each peripheral surface 123, which defines an engagement portion 124 of the conductive layer 12. The bonding layer 39 is also in contact with the upper edge 123A of each peripheral surface 123. As shown in FIGS. 9 and 10, each bonding portion 312 has an upper surface 312A that faces the same side as the mounting surface 121 of the conductive layer 12 in the first direction z. The bonding layer 39 is in contact with the edge of each upper surface 312A.

As shown in FIGS. 2 and 5, the second terminal 32 is electrically bonded to the two second electrodes 212 of the first semiconductor element 21 and the two fourth electrodes 222 of the second semiconductor element 22. This electrically connects the second terminal 32 to each second electrode 212 and each fourth electrode 222. Thus, the second terminal 32 is the source terminal of the semiconductor device A10. The second terminal 32 contains copper.

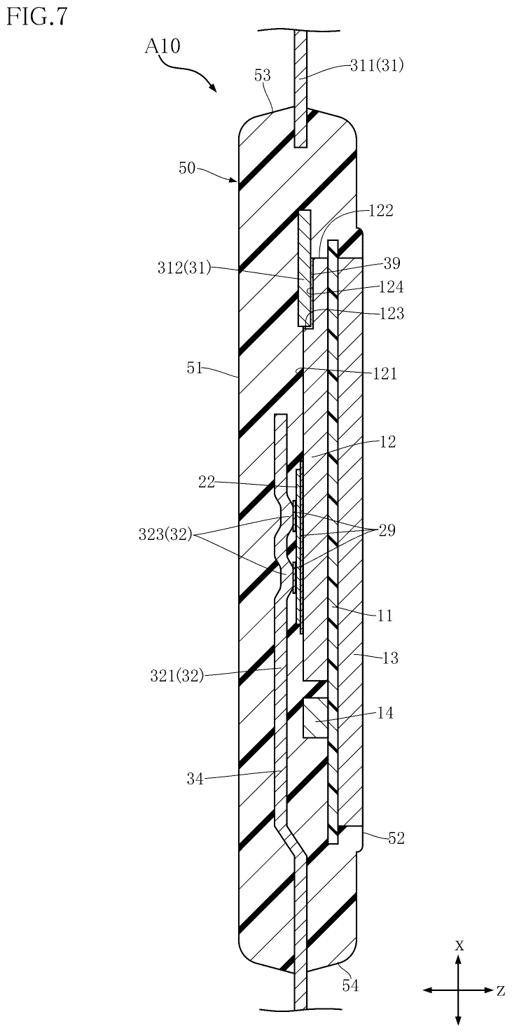

As shown in FIGS. 2 and 5, the second terminal 32 has a base portion 321, a plurality of first bonding portions 322, and a plurality of second bonding portions 323. As viewed in the first direction z, the base portion 321 overlaps with the mounting surface 121 of the conductive layer 12. As shown in FIG. 1, the base portion 321 includes a portion covered with the sealing resin 50 and a portion exposed to the outside from the second side surface 54 of the sealing resin 50. The first bonding portions 322 are connected to the base portion 321 and are covered with the sealing resin 50. As shown in FIG. 6, the first bonding portions 322 protrude from the base portion 321 toward the first semiconductor element 21. Each first bonding portion 322 is electrically bonded to a second electrode 212 of the first semiconductor element 21 via a conductive bonding layer 29. The second bonding portions 323 are connected to the base portion 321 and are covered with the sealing resin 50. As shown in FIG. 7, the second bonding portions 323 protrude from the base portion 321 toward the second semiconductor element 22. Each second bonding portion 323 is electrically bonded to a fourth electrode 222 of the second semiconductor element 22 via a conductive bonding layer 29.

As shown in FIG. 1, the first signal terminal 33 includes a portion covered with the scaling resin 50 and a portion exposed to the outside from the second side surface 54 of the sealing resin 50. The first signal terminal 33 is located on one side of the base portion 321 of the second terminal 32 in the third direction y. The first signal terminal 33 is electrically connected to the first wiring layer 14. Thus, the first signal terminal 33 is electrically connected to the first gate electrode 213 of the first semiconductor element 21 and the second gate electrode 223 of the second semiconductor element 22. In short, the first signal terminal 33 is the gate terminal of the semiconductor device A10. The first signal terminal 33 contains copper. As shown in FIG. 4, the exposed portion of the first signal terminal 33, which protrudes from the second side surface 54, includes a portion extending in the first direction z.

As shown in FIG. 1, the second signal terminal 34 includes a portion covered with the sealing resin 50 and a portion exposed to the outside from the second side surface 54 of the sealing resin 50. The second signal terminal 34 is located between the first signal terminal 33 and the second terminal 32 of the base portion 321 in the third direction y. In the semiconductor device A10, the second signal terminal 34 is connected to the base portion 321. Thus, the second signal terminal 34 is electrically connected to each second electrode 212 and each fourth electrode 222. The second signal terminal 34 receives the voltage equal to that applied to the second electrodes 212 and the fourth electrodes 222. The second signal terminal 34 contains copper. Like the exposed portion of the first signal terminal 33, the exposed portion of the second signal terminal 34, which protrudes from the second side surface 54, includes a portion extending in the first direction z.

As shown in FIG. 2, the first conductive member 41 is electrically bonded to the first gate electrode 213 of the first semiconductor element 21 and to the first wiring layer 14. This electrically connects the first wiring layer 14 to the first gate electrode 213. The first conductive member 41 is covered with the sealing resin 50. For example, the first conductive member 41 is a wire that contains either aluminum (Al) or gold (Au).

As shown in FIG. 2, the second conductive member 42 is electrically bonded to the second gate electrode 223 of the second semiconductor element 22 and to the first wiring layer 14. This electrically connects the first wiring layer 14 to the second gate electrode 223. The second conductive member 42 is covered with the sealing resin 50. For example, the second conductive member 42 is a wire that contains either aluminum or gold. The second conductive member 42 has a length equal to that of the first conductive member 41.

As shown in FIG. 2, the third conductive member 43 is electrically bonded to the first wiring layer 14 and the first signal terminal 33. This electrically connects the first wiring layer 14 to the first signal terminal 33. The third conductive member 43 is covered with the scaling resin 50. For example, the third conductive member 43 is a wire that contains either aluminum or gold. In the semiconductor device A10, the third conductive member 43 is connected to the second conductive member 42.

As shown in FIG. 2, the first signal terminal 33 has a first contact point Ca as viewed in the first direction z. The third conductive member 43 is electrically bonded to the first contact point Ca. The location of the first contact point Ca is not specifically limited, as long as it falls within the portion of the first signal terminal 33 that is covered with the sealing resin 50.

Here, as shown in FIG. 2, a first straight-line length L1, a second straight-line length L2, a first conductive-path length R1, and a second conductive-path length R2 are defined. The first straight-line length L1 is the shortest distance between the first center C1 of the first gate electrode 213 of the first semiconductor element 21 and the first contact point Ca of the first signal terminal 33. The second straight-line length L2 is the shortest distance between the second center C2 of the second gate electrode 223 of the second semiconductor element 22 and the first contact point Ca. The first conductive-path length R1 is the length of the shortest conductive path from the first center C1 to the first contact point Ca via the first conductive member 41, the first wiring layer 14, and the third conductive member 43. The second conductive-path length R2 is the length of the shortest conductive path from the second center C2 to the first contact point Ca via the second conductive member 42, the first wiring layer 14, and the third conductive member 43. When the ratio of the second straight-line length L2 to the first straight-line length L1 and the ratio of the second conductive-path length R2 to the first conductive-path length R1 are compared, the semiconductor device A10 satisfies that R2/R1 is closer to 1 than L2/L1 is. Using the absolute value symbol (| |), this relation is written as |1−L2/L1|>|1−R2/R1|.

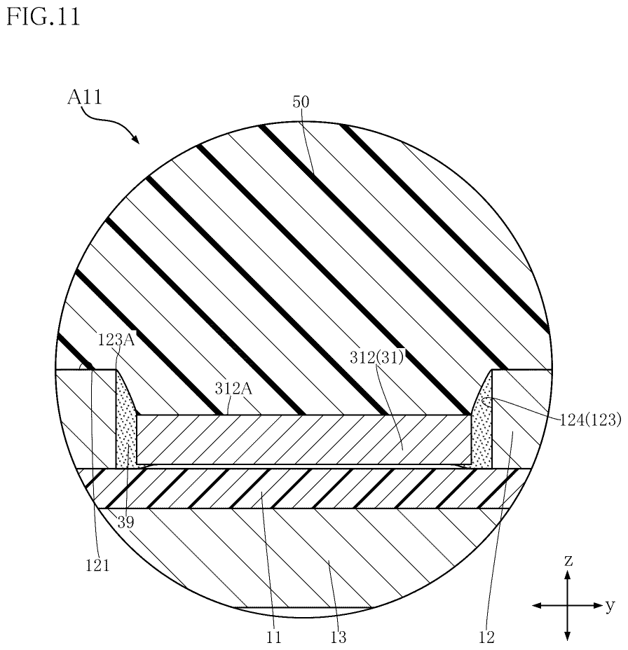

Next, with reference to FIG. 11, the following describes a semiconductor device A11 according to a first variation of the semiconductor device A10. FIG. 11 shows a section taken along the same line as the section shown in FIG. 10.

As shown in FIG. 11, the semiconductor device A11 features that the entirety of each bonding portion 312 of the first terminal 31 is accommodated in the corresponding engagement portion 124 of the conductive layer 12. In the semiconductor device A11, each engagement portion 124 is a slit that extends through the conductive layer 12 in the first direction z. The semiconductor device A11 ensures that the bonding layer 39 is in contact with the upper edge 123A of each peripheral surface 123. The bonding layer 39 is also in contact with the edge of the upper surface 312A of each bonding portion 312. The bonding layer 39 is solder, for example.

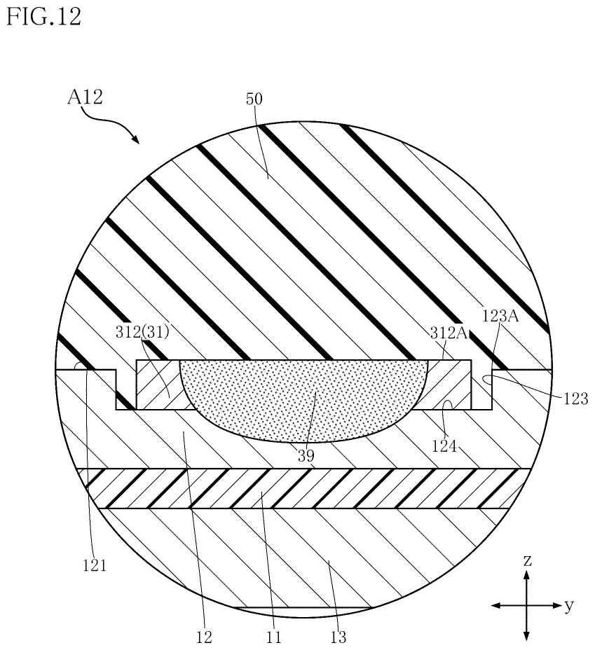

Next, with reference to FIG. 12, the following describes a semiconductor device A12 according to a second variation of the semiconductor device A10. FIG. 12 shows a section taken along the same line as the section shown in FIG. 10.

The semiconductor device A12 features that each bonding portion 312 of the first terminal 31 is electrically bonded to a corresponding engagement portion 124 of the conductive layer 12 by welding, such as laser welding. During welding, a portion of the conductive layer 12 forming an engagement portion 124 and an adjacent portion of the bonding portion 312 melt and fuse together into molten metal, which solidifies to forms the weld. In the semiconductor device A12, the solidified molten metal is the bonding layer 39.

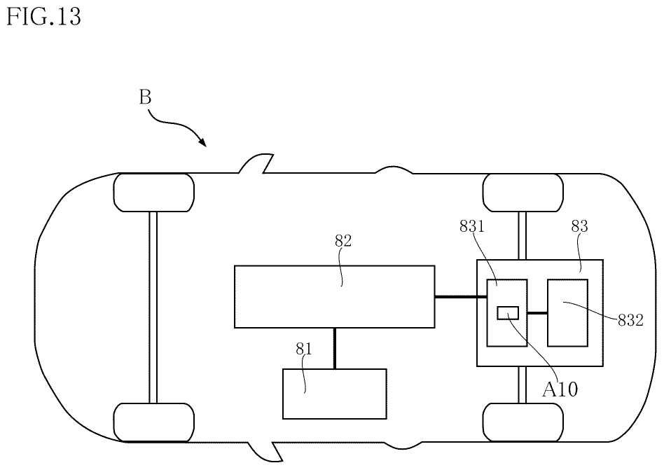

Next, with reference to FIG. 13, the following describes a vehicle B equipped with a semiconductor device A10. The vehicle B is an electric vehicle (EV), for example.

As shown in FIG. 13, the vehicle B includes an on-board charger 81, a storage battery 82, and a drive system 83. The on-board charger 81 is supplied with power wirelessly from an outdoor power supply facility (not shown). In other example, the on-board charger 81 may be supplied with power from an outdoor power supply facility via a wired connection. The on-board charger 81 includes a step-up DC-DC converter. The on-board charger 81 increases the input voltage and supplies the resulting power to the storage battery 82. The voltage is increased to 600 V, for example.

The drive system 83 propels the vehicle B. The drive system 83 includes an inverter 831 and a drive source 832. The semiconductor device A10 forms a part of the inverter 831. The power stored on the storage battery 82 is supplied to the inverter 831. The storage battery 82 supplies DC power to the inverter 831. Unlike the power system shown in FIG. 13, another step-up DC-DC converter may be additionally provided between the storage battery 82 and the inverter 831. The inverter 831 converts DC power to AC power. The inverter 831, which includes the semiconductor device A10, is electrically connected to the drive source 832. The drive source 832 includes an AC motor and a transmission. Supplied with AC power from the inverter 831, the drive source 832 rotates the AC motor, and the rotation is transmitted to the transmission. The transmission reduces the rotational speed transmitted from the AC motor as needed and rotates the axle of the vehicle B. This propels the vehicle B. During operation of the vehicle B, the rotational speed of the AC motor needs to be adjusted based on, for example, the pressed amount of the accelerator pedal. To this end, the inverter 831 of the semiconductor device A10 adjusts the frequency of the AC power to match the rotational speed of the AC motor as needed.

The following describes advantages of the semiconductor device A10.

The semiconductor device A10 includes a conductive layer 12, a first semiconductor element 21, a second semiconductor element 22, and a first signal terminal 33. The first semiconductor element 21 includes a first gate electrode 213. The second semiconductor element 22 includes a second gate electrode 223. Here, let L1 denote a first straight-line length connecting a first center C1 of the first gate electrode 213 and a first contact point Ca of the first signal terminal 33, and L2 denote a second straight-line length connecting a second center C2 of the second gate electrode 223 and the first contact point Ca. Additionally, let R1 denote a first conductive-path length from the first center C1 to the first contact point Ca, and R2 denote a second conductive-path length from the second center C2 to the first contact point Ca. When the ratio of the second straight-line length L2 to the first straight-line length L1 and the ratio of the second conductive-path length R2 to the first conductive-path length R1 are compared, the semiconductor device A10 satisfies that R2/R1 is closer to 1 than L2/L1 is (see FIG. 2). This configuration ensures that the second conductive-path length R2 is substantially equal to the first conductive-path length R1. This prevents or reduces resonance that occurs due to the interaction between the current flowing through the conductive path with the first conductive-path length R1 and the current flowing through the conductive path with the second conductive-path length R2. The semiconductor device A10 of this configuration is therefore enabled to prevent or reduce resonance phenomena that occur when the plurality of semiconductor elements operate in parallel.

The semiconductor device A10 additionally includes a first terminal 31 that is electrically connected to the first semiconductor element 21, and a bonding layer 39 that electrically bonds the conductive layer 12 and the first terminal 31. The conductive layer 12 includes a peripheral surface 123 defining an engagement portion 124. The first terminal 31 includes a bonding portion 312 electrically bonded to the engagement portion 124. The bonding layer 39 electrically bonds the engagement portion 124 and the bonding portion 312. The bonding layer 39 is in contact with the peripheral surface 123. As viewed in the first direction z, the bonding portion 312 overlaps with the engagement portion 124. This configuration achieves the following during the process of bonding the bonding portion 312 to the engagement portion 124 via the bonding layer 39. If the bonding portion 312 shifts in a direction perpendicular to the first direction z, the bonding layer 39, which is in a molten state, is forced against the peripheral surface 123. In response, the peripheral surface 123 exerts a reaction force on the molten-state bonding layer 39 in the direction perpendicular to the first direction z. As a result, the molten-state bonding layer 39 produces the self-alignment effect on the bonding portion 312. Due to the self-alignment effect, the bonding portion 312 is retained on the position overlapping with the engagement portion 124 as viewed in the first direction z. This configuration thus prevents or reduces misalignment of the first terminal 31 with the conductive layer 12.

For the self-alignment effect to be more significant, it is preferable for the bonding layer 39 to be in contact with the upper edge 123A of the peripheral surface 123 of the conductive layer 12. This configuration ensures that a higher surface tension is exerted on the molten-state bonding layer 39.

In the semiconductor device A10, at least a portion of the bonding portion 312 of the first terminal 31 is accommodated in the engagement portion 124. This configuration ensures that the peripheral surface 123 of the conductive layer 12 exerts a greater reaction force on the molten-state bonding layer 39, thereby preventing or reducing misalignment of the bonding portion 312 more efficiently. This configuration thus efficiently prevents or reduces misalignment of the first terminal 31 with the conductive layer 12, and also prevents rotation of the first terminal 31 around the axis in the first direction z.

The bonding portion 312 of the first terminal 31 has the upper surface 312A that faces the same side as the mounting surface 121 of the conductive layer 12 in the first direction z. The bonding layer 39 is in contact with the edge of each upper surface 312A. This configuration ensures that the molten-state bonding layer 39 produces greater surface tension, thereby achieving the self-alignment effect more efficiently.

The semiconductor device A10 further includes: an insulating layer 11 bonded to the conductive layer 12; and a heat dissipation layer 13 that is located on the opposite side of the insulating layer 11 from the conductive layer 12 and is bonded to the insulating layer 11. The insulating layer 11 and the conductive layer 12 are covered with the sealing resin 50. The heat dissipation layer 13 is exposed to the outside from the sealing resin 50. This configuration prevents a decrease in the dielectric strength of the semiconductor device A10 and improves the heat dissipation of the semiconductor device A10.

As viewed in the first direction z, the conductive layer 12 and the heat dissipation layer 13 are each spaced apart from the periphery 111 of the insulating layer 11. With this configuration, the sealing resin 50 sandwiches the periphery 111 and its adjacent portion of the insulating layer 11 from both sides in the first direction z. This is effective for preventing delamination of the insulating layer 11 and the conductive layer 12 from the sealing resin 50.

The dimension of each of the conductive layer 12 and the heat dissipation layer 13 in the first direction z is larger than the dimension of the insulating layer 11 in the first direction z. This configuration is effective for reducing the thermal resistance of the conductive layer 12 and the heat dissipation layer 13 in the first direction z. This further improves the heat dissipation of the semiconductor device A10.

### Second Embodiment

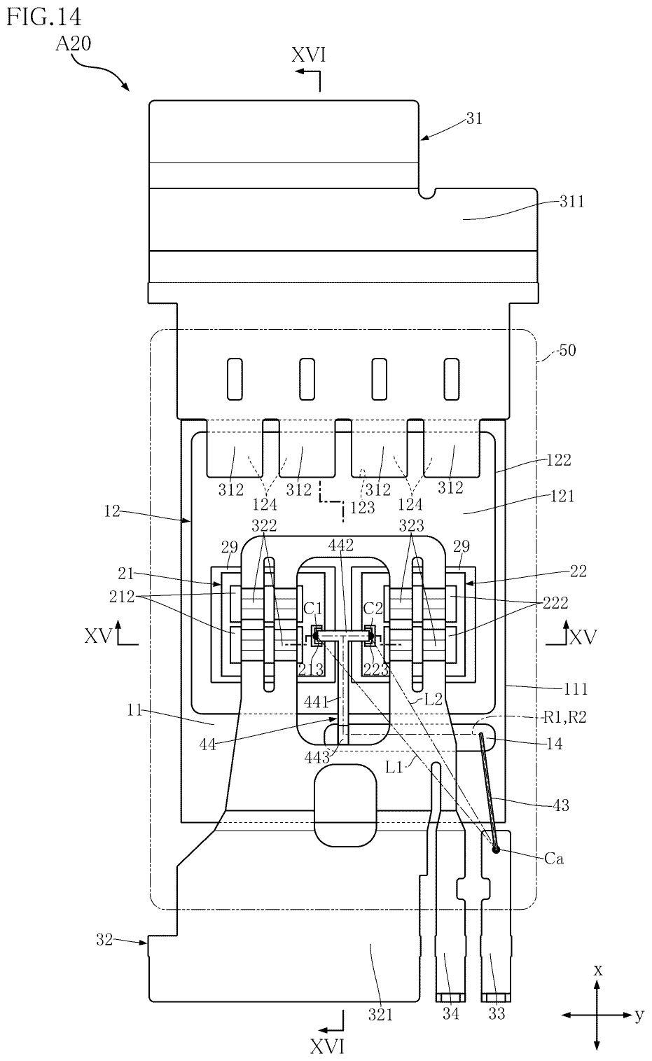

With reference to FIGS. 14 to 18, the following describes a semiconductor device A20 according to a second embodiment of the present disclosure. In these figures, elements that are identical or similar to those of the semiconductor device A10 described above are denoted by the same reference numerals, and redundant descriptions are omitted. For convenience, FIG. 14 shows the sealing resin 50 as transparent. The outline of the sealing resin 50 is indicated by imaginary lines in FIG. 14.

Compared with the semiconductor device A10, the semiconductor device A20 includes a conductive member 44 instead of the first conductive member 41 and the second conductive member 42, additionally includes a first bonding layer 37, and differs in the configuration of the first wiring layer 14.

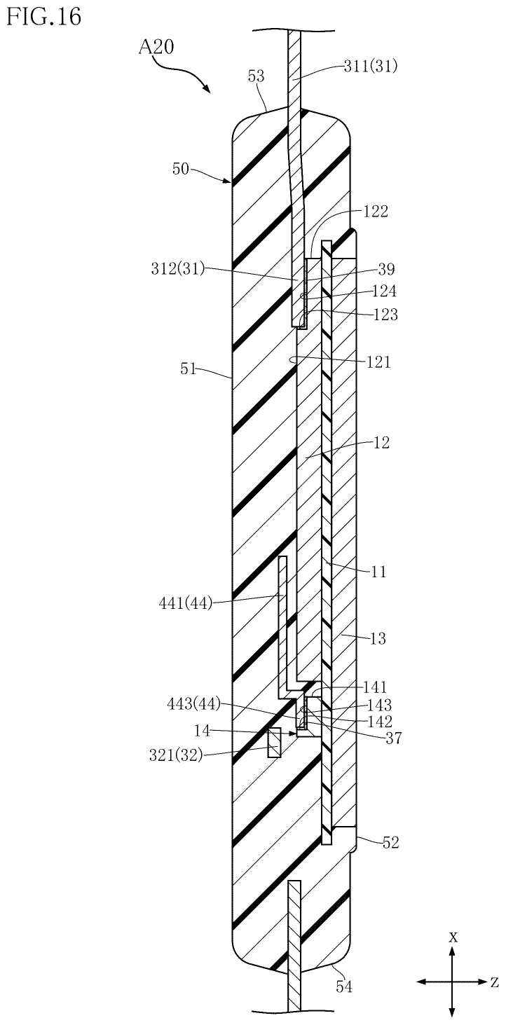

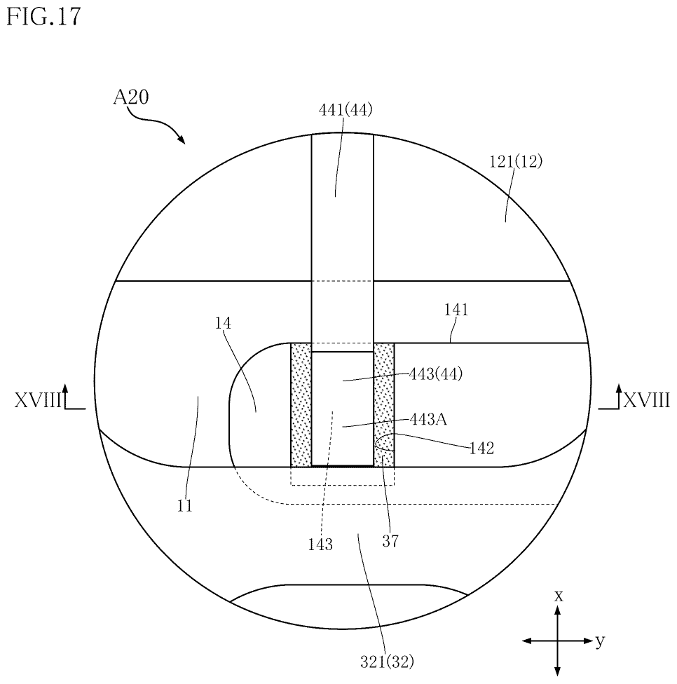

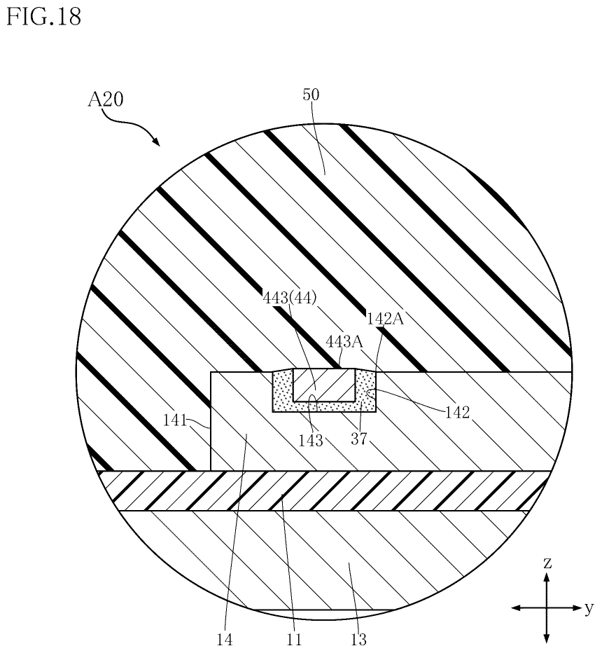

As shown in FIGS. 16 and 17, the first wiring layer 14 has a first end surface 141 and a first peripheral surface 142. The first end surface 141 faces in a direction perpendicular to the first direction z. The first peripheral surface 142 faces in a direction perpendicular to the first direction z and is located inward of the first wiring layer 14 from the first end surface 141 as viewed in the first direction z. As shown in FIG. 18, the first peripheral surface 142 has a first upper edge 142A. The first upper edge 142A is a boundary between the first peripheral surface 142 and the surface of the first wiring layer 14 facing the same side as the mounting surface 121 of the conductive layer 12 in the first direction z.

As shown in FIGS. 16 and 18, the first wiring layer 14 has a first engagement portion 143. The first engagement portion 143 is defined by the first peripheral surface 142. The first engagement portion 143 is a recess that is recessed in the first direction z.

As shown in FIGS. 14 to 16, the conductive member 44 is electrically bonded to the first gate electrode 213 of the first semiconductor element 21, the second gate electrode 223 of the second semiconductor element 22, and the first engagement portion 143 of the first wiring layer 14. The conductive member 44 is a metal lead containing copper. The conductive member 44 is covered with the sealing resin 50.

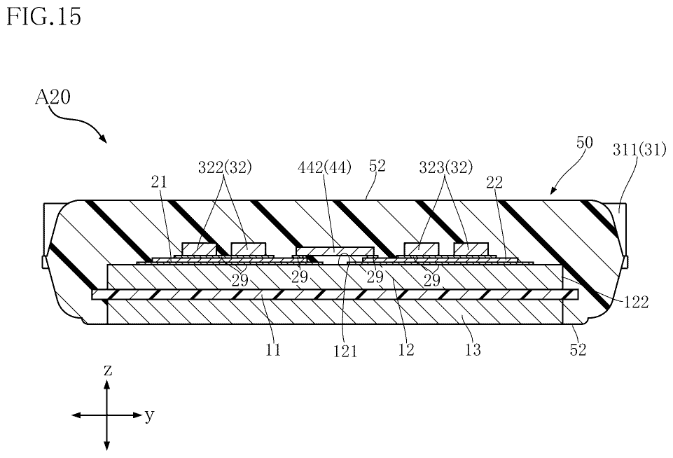

As shown in FIG. 14, the conductive member 44 includes a base portion 441, a first connecting portion 442, and a second connecting portion 443. The base portion 441 extends in the second direction x. The first connecting portion 442 is connected to one end of the base portion 441 in the second direction x. The first connecting portion 442 extends in the third direction y. As shown in FIG. 15, one end of the first connecting portion 442 in the third direction y is electrically bonded to the first gate electrode 213 via a conductive bonding layer 29. The other end of the first connecting portion 442 in the third direction y is electrically bonded to the second gate electrode 223 via a conductive bonding layer 29. The second connecting portion 443 is located at the opposite end of the base portion 441 from the first connecting portion 442 and is connected to the base portion 441. As shown in FIG. 16, at least a portion of the second connecting portion 443 is accommodated in the first engagement portion 143 of the first wiring layer 14.

As shown in FIG. 18, the first bonding layer 37 is electrically bonded to the first engagement portion 143 of the first wiring layer 14 and the second connecting portion 443 of the conductive member 44. This electrically connects the first gate electrode 213 of the first semiconductor element 21 and the second gate electrode 223 of the second semiconductor element 22 to the first wiring layer 14. The first bonding layer 37 is solder, for example.

As shown in FIG. 18, the first bonding layer 37 is in contact with the first peripheral surface 142, which defines the first engagement portion 143 of the first wiring layer 14. The first bonding layer 37 is also in contact with the first upper edge 142A of the first peripheral surface 142. As shown in FIGS. 17 and 18, the second connecting portion 443 of the conductive member 44 has an upper surface 443A facing the same side as the mounting surface 121 of the conductive layer 12 in the first direction z. The first bonding layer 37 is in contact with the edge of the upper surface 443A.

The following describes advantages of the semiconductor device A20.

The semiconductor device A20 includes: a conductive layer 12, a first semiconductor element 21, a second semiconductor element 22, and a first signal terminal 33. The first semiconductor element 21 includes a first gate electrode 213. The second semiconductor element 22 includes a second gate electrode 223. Here, let L1 denote a first straight-line length connecting a first center C1 of the first gate electrode 213 and a first contact point Ca of the first signal terminal 33, and L2 denote a second straight-line length connecting a second center C2 of the second gate electrode 223 and the first contact point Ca. Additionally, let R1 denote a first conductive-path length from the first center C1 to the first contact point Ca, and R2 denote a second conductive-path length from the second center C2 to the first contact point Ca. When the ratio of the second straight-line length L2 to the first straight-line length L1 and the ratio of the second conductive-path length R2 to the first conductive-path length R1 are compared, the semiconductor device A20 satisfies that R2/R1 is closer to 1 than L2/L1 is (see FIG. 14). The semiconductor device A20 of this configuration is therefore enabled to prevent or reduce resonance phenomena that occur when the plurality of semiconductor elements operate in parallel. Additionally, the semiconductor device A20 has a configuration in common with the semiconductor device A10, thereby achieving the same effect as the semiconductor device A10.

The semiconductor device A20 includes a conductive member 44 instead of the first conductive member 41 and the second conductive member 42, and additionally includes a first bonding layer 37 that electrically bonds the first wiring layer 14 and the conductive member 44. The first wiring layer 14 includes a first peripheral surface 142 defining a first engagement portion 143. The conductive member 44 includes a second connecting portion 443 that is electrically bonded to the first engagement portion 143 via the first bonding layer 37. The first bonding layer 37 is in contact with the first peripheral surface 142. At least a portion of the second connecting portion 443 is accommodated in the first engagement portion 143. This configuration achieves the following during the process of electrically bonding the second connecting portion 443 to the first engagement portion 143 via the first bonding layer 37. If the second connecting portion 443 shifts in a direction perpendicular to the first direction z, the first peripheral surface 142 exerts a reaction force on the molten-state first bonding layer 37 in the direction perpendicular to the first direction z. Then, misalignment of the second connecting portion 443 is prevented or reduced by the first peripheral surface 142. This configuration thus efficiently prevents or reduces misalignment of the conductive member 44 with the first wiring layer 14, and also prevents rotation of the conductive member 44 around the axis in the first direction z.

### Third Embodiment

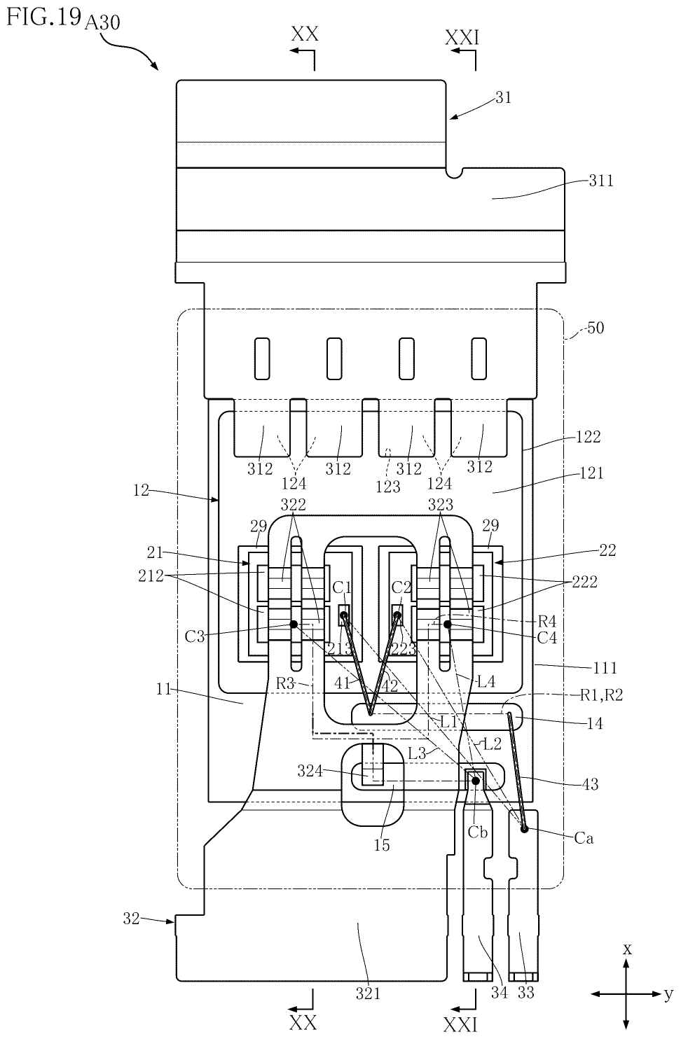

With reference to FIGS. 19 to 23, the following describes a semiconductor device A30 according to a third embodiment of the present disclosure. In these figures, elements that are identical or similar to those of the semiconductor device A10 described above are denoted by the same reference numerals, and redundant descriptions are omitted. For convenience, FIG. 19 shows the sealing resin 50 as transparent. The outline of the sealing resin 50 is indicated by imaginary lines in FIG. 19.

Compared with the semiconductor device A10, the semiconductor device A30 additionally includes a second wiring layer 15 and a second bonding layer 38 and differs in the configurations of the second terminal 32 and the second signal terminal 34.

As shown in FIGS. 19 to 21, the second wiring layer 15 is located on the same side as the conductive layer 12 with respect to the insulating layer 11 and is bonded to the insulating layer 11. The second wiring layer 15 is located on the opposite side of the first wiring layer 14 from the conductive layer 12 in the second direction x. The second wiring layer 15 extends in the third direction y. As viewed in the first direction z, the second wiring layer 15 is enclosed within the periphery 111 of the insulating layer 11. The second wiring layer 15 is covered with the sealing resin 50. The second wiring layer 15 contains copper. The dimension of the second wiring layer 15 in the first direction z is larger than the dimension of the insulating layer 11 in the first direction z.

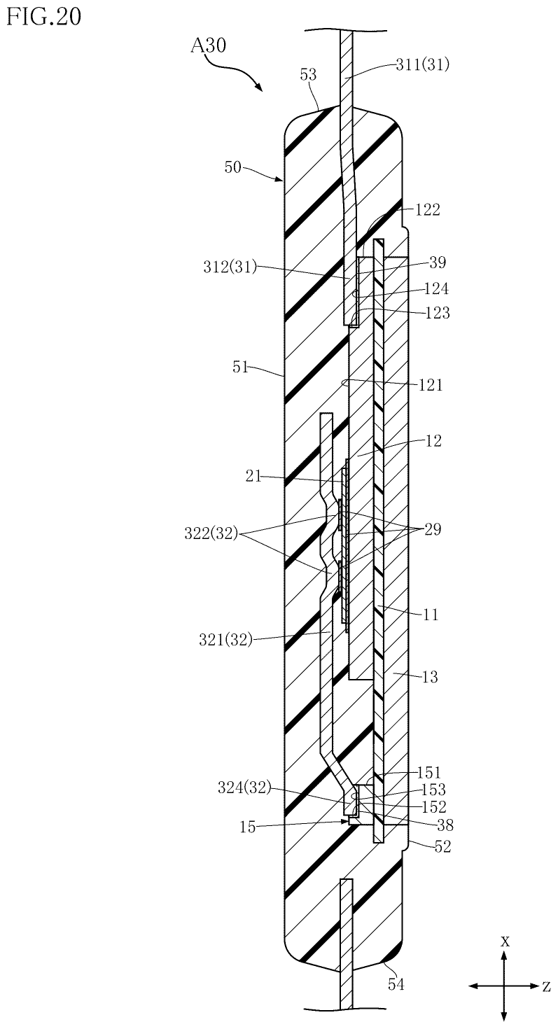

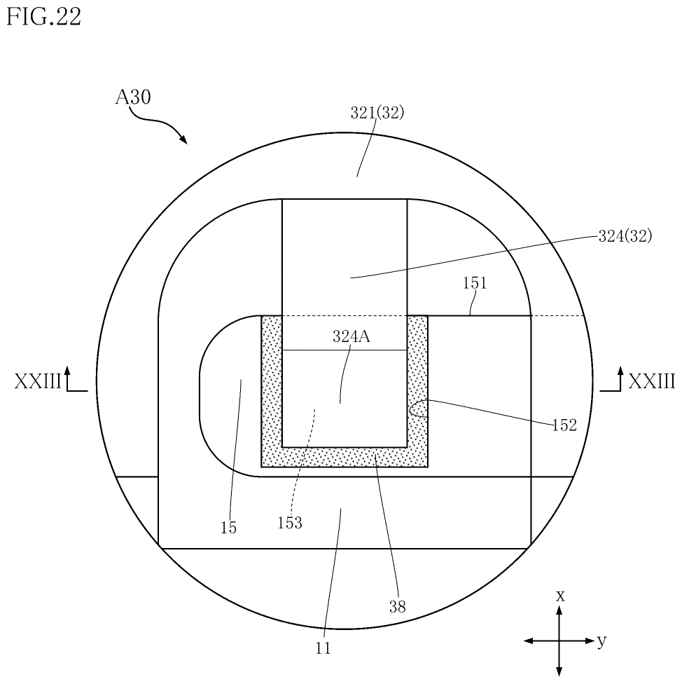

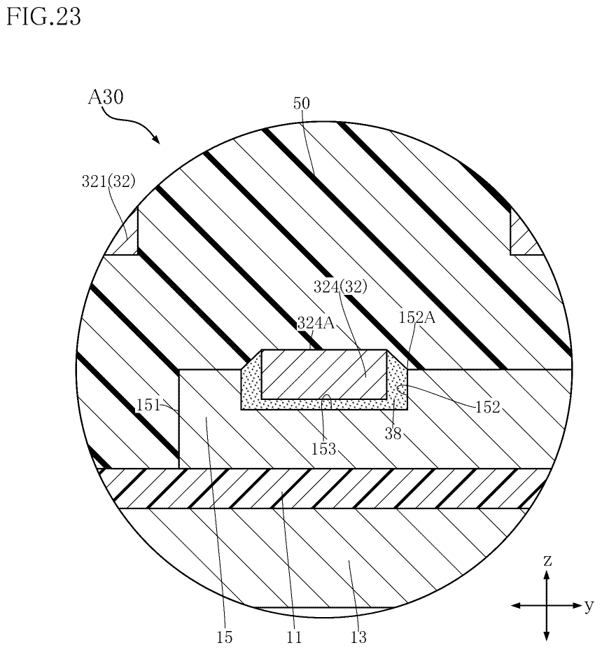

As shown in FIGS. 20 and 22, the second wiring layer 15 has a second end surface 151 and a second peripheral surface 152. The second end surface 151 faces in a direction perpendicular to the first direction z. The second peripheral surface 152 faces in a direction perpendicular to the first direction z and is located inward of the second wiring layer 15 from the second end surface 151 as viewed in the first direction z. As shown in FIG. 23, the second peripheral surface 152 has a second upper edge 152A. The second upper edge 152A is a boundary between the second peripheral surface 152 and the surface of the second wiring layer 15 facing the same side as the mounting surface 121 of the conductive layer 12 in the first direction z.

As shown in FIGS. 20 and 23, the second wiring layer 15 has a second engagement portion 153. The second engagement portion 153 is defined by the second peripheral surface 152. The second engagement portion 153 is a recess that is recessed in the first direction z.

As shown in FIGS. 19 and 20, the second terminal 32 has a supporting portion 324. The supporting portion 324 is connected to the base portion 321 of the second terminal 32. The supporting portion 324 is covered with the scaling resin 50. In the third direction y, the supporting portion 324 is located between the first bonding portions 322 of the second terminal 32 and the second bonding portions 323 of the second terminal 32. As shown in FIG. 20, at least a portion of the supporting portion 324 is accommodated in the second engagement portion 153 of the second wiring layer 15.

As shown in FIG. 23, the second bonding layer 38 electrically bonds the second engagement portion 153 of the second wiring layer 15 and the supporting portion 324 of the second terminal 32. This electrically connects the second wiring layer 15 to the second terminal 32, each of the two second electrodes 212 of the first semiconductor element 21, and each of the two fourth electrodes 222 of the second semiconductor element 22.

As shown in FIG. 23, the second bonding layer 38 is in contact with the second peripheral surface 152, which defines the second engagement portion 153 of the second wiring layer 15. The second bonding layer 38 is also in contact with the second upper edge 152A of the second peripheral surface 152. As shown in FIGS. 22 and 23, the supporting portion 324 of the second terminal 32 has an upper surface 324A that faces the same side as the mounting surface 121 of the conductive layer 12 in the first direction z. The second bonding layer 38 is in contact with the edge of the upper surface 324A.

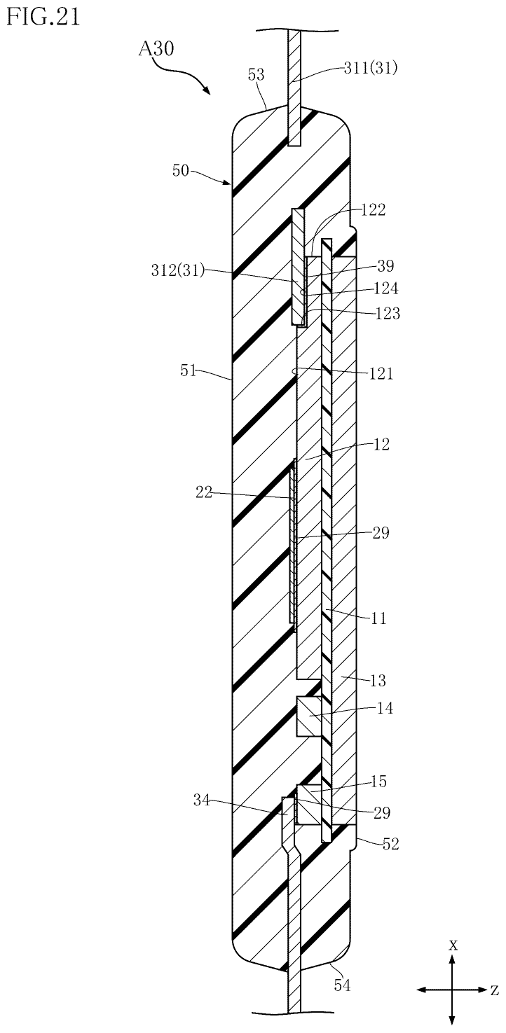

As shown in FIG. 19, the second signal terminal 34 is spaced apart from the second terminal 32. As shown in FIG. 21, the second signal terminal 34 is electrically bonded to the second wiring layer 15 via a conductive bonding layer 29. This electrically connects the second signal terminal 34 to the second wiring layer 15.

As shown in FIG. 19, the second signal terminal 34 has a second contact point Cb as viewed in the first direction z. The second contact point Cb overlaps with the second wiring layer 15 as viewed in the first direction z. The location of the second contact point Cb is not specifically limited, as long as it falls within the portion of the second signal terminal 34 that is covered with the sealing resin 50.

As shown in FIG. 19, the two second electrodes 212 of the first semiconductor element 21 are rectangular as viewed in the first direction z. As viewed in the first direction z, one of the two second electrodes 212 that is closer to the second signal terminal 34 has a third center C3. The third center C3 is the intersection point of the diagonals of the relevant second electrode 212.

As shown in FIG. 19, the two four electrodes 222 of the second semiconductor element 22 are rectangular as viewed in the first direction z. As viewed in the first direction z, one of the two fourth electrodes 222 that is closer to the second signal terminal 34 has a fourth center C4. The fourth center C4 is the intersection point of the diagonals of the relevant fourth electrode 222.

Here, as shown in FIG. 3, a third straight-line length L3, a fourth straight-line length L4, a third conductive-path length R3, and a fourth conductive-path length R4 are defined. The third straight-line length L3 is the shortest distance between the third center C3 of the relevant one of the two second electrodes 212 of the first semiconductor element 21 and the second contact point Cb of the second signal terminal 34. The fourth straight-line length L4 is the shortest distance between the fourth center C4 of the relevant one of the two fourth electrodes 222 of the second semiconductor element 22 and the second contact point Cb. The third conductive-path length R3 is the length of the shortest conductive path from the third center C3 to the second contact point Cb via the second terminal 32 and the second wiring layer 15. The fourth conductive-path length R4 is the length of the shortest conductive path from the fourth center C4 to the second contact point Cb via the second terminal 32 and the second wiring layer 15. When the ratio of the third straight-line length L3 to the fourth straight-line length L4 and the ratio of the third conductive-path length R3 to the fourth conductive-path length R4 are compared, the semiconductor device A30 satisfies that R3/R4 is closer to 1 than L3/L4 is.

The following describes advantages of the semiconductor device A30.

The semiconductor device A30 includes a conductive layer 12, a first semiconductor element 21, a second semiconductor element 22, and a first signal terminal 33. The first semiconductor element 21 includes a first gate electrode 213. The second semiconductor element 22 includes a second gate electrode 223. Here, let L1 denote a first straight-line length connecting a first center C1 of the first gate electrode 213 and a first contact point Ca of the first signal terminal 33, and L2 denote a second straight-line length connecting a second center C2 of the second gate electrode 223 and the first contact point Ca. Also, let R1 denote a first conductive-path length from the first center C1 to the first contact point Ca, and R2 denote a second conductive-path length from the second center C2 to the first contact point Ca. When the ratio of the second straight-line length L2 to the first straight-line length L1 and the ratio of the second conductive-path length R2 to the first conductive-path length R1 are compared, the semiconductor device A30 satisfies that R2/R1 is closer to 1 than L2/L1 is (see FIG. 19). The semiconductor device A30 of this configuration is therefore enabled to prevent or reduce resonance phenomena that occur when the plurality of semiconductor elements operate in parallel. Additionally, the semiconductor device A30 has a configuration in common with the semiconductor device A10, thereby achieving the same effect as the semiconductor device A10.

The semiconductor device A30 additionally includes a second signal terminal 34. The first semiconductor element 21 includes a first electrode 211 electrically bonded to the conductive layer 12 and a second electrode 212 electrically connected to the second signal terminal 34. The second semiconductor element 22 includes a third electrode 221 electrically bonded to the conductive layer 12 and a fourth electrode 222 electrically connected to the second signal terminal 34. Here, let L3 denote a third straight-line length connecting a third center C3 of the second electrode 212 and a second contact point Cb of the second signal terminal 34, and L4 denote a fourth straight-line length connecting a fourth center C4 of the fourth electrode 222 and the second contact point Cb. Also, let R3 denote a third conductive-path length from the third center C3 to the second contact point Cb, and R4 denote a fourth conductive-path length from the fourth center C4 to the second contact point Cb. When the ratio of the fourth straight-line length L4 to the third straight-line length L3 and the ratio of the fourth conductive-path length R4 to the third conductive-path length R3 are compared, the semiconductor device A30 satisfies that R4/R3 is closer to 1 than L4/L3 is (see FIG. 19). This configuration ensures that the fourth conductive-path length R4 is substantially equal to the third conductive-path length R3. This prevents or reduces resonance that occurs due to the interaction between the current flowing through the conductive path with the third conductive-path length R3 and the current flowing through the conductive path with the fourth conductive-path length R4. The semiconductor device A30 of this configuration is therefore enabled to prevent or reduce resonance phenomena that occur when the plurality of semiconductor elements operate in parallel.

The semiconductor device A30 additionally includes a second wiring layer 15, and a second bonding layer 38 that electrically bonds the second wiring layer 15 and the second terminal 32. The second wiring layer 15 includes a second peripheral surface 152 defining a second engagement portion 153. The second terminal 32 has a supporting portion 324 that is electrically bonded to the second engagement portion 153 via a second bonding layer 38. The second bonding layer 38 is in contact with the second peripheral surface 152. At least a portion of the supporting portion 324 is accommodated in second engagement portion 153. This configuration achieves the following during the process of electrically bonding the supporting portion 324 to the second engagement portion 153 via the second bonding layer 38. If the supporting portion 324 shifts in a direction perpendicular to the first direction z, the second peripheral surface 152 exerts a reaction force on the molten-state second bonding layer 38 in the direction perpendicular to the first direction z. Then, misalignment of the supporting portion 324 is prevented or reduced by the second peripheral surface 152. This configuration thus efficiently prevents or reduces misalignment of the second terminal 32 with the second wiring layer 15, and also prevents rotation of the second terminal 32 around the axis in the first direction z.

The supporting portion 324 of the second terminal 32 is connected to the base portion 321 of the second terminal 32. The supporting portion 324 is located between the first bonding portion 322 and the second bonding portion 323 of the second terminal 32 in a direction perpendicular to the first direction z. This consequently ensures that the conduction path length from the fourth electrode 222 of the second semiconductor element 22 to the second wiring layer 15 closely matches the conduction path length from the second electrode 212 of the first semiconductor element 21 to the second wiring layer 15. This more efficiently ensures that the fourth conductive-path length R4 is substantially equal to the third conductive-path length R3.

### Fourth Embodiment

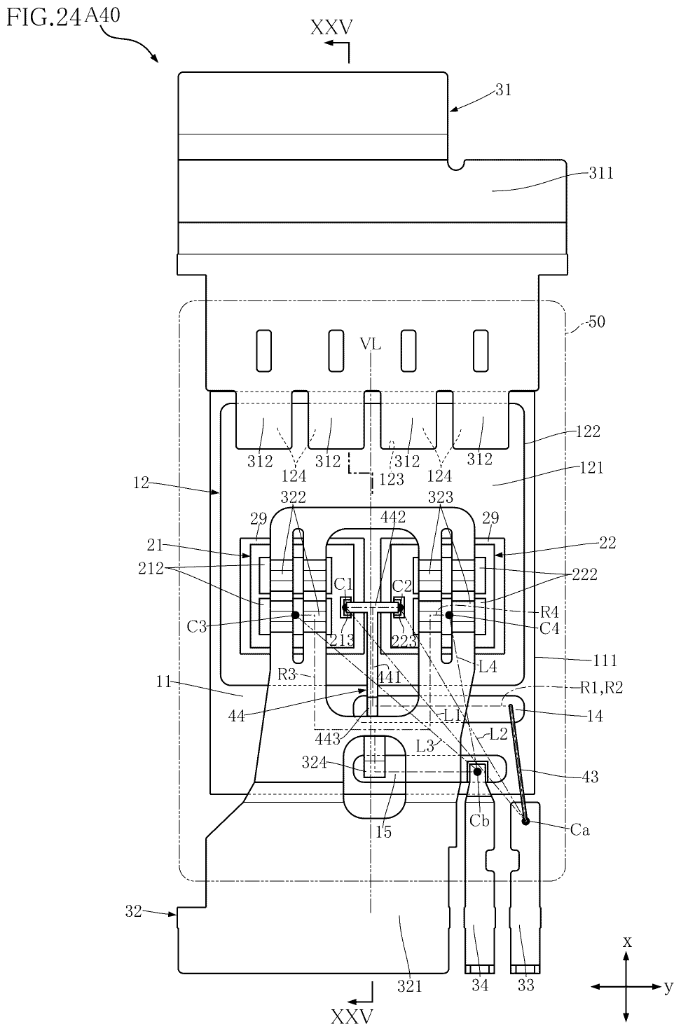

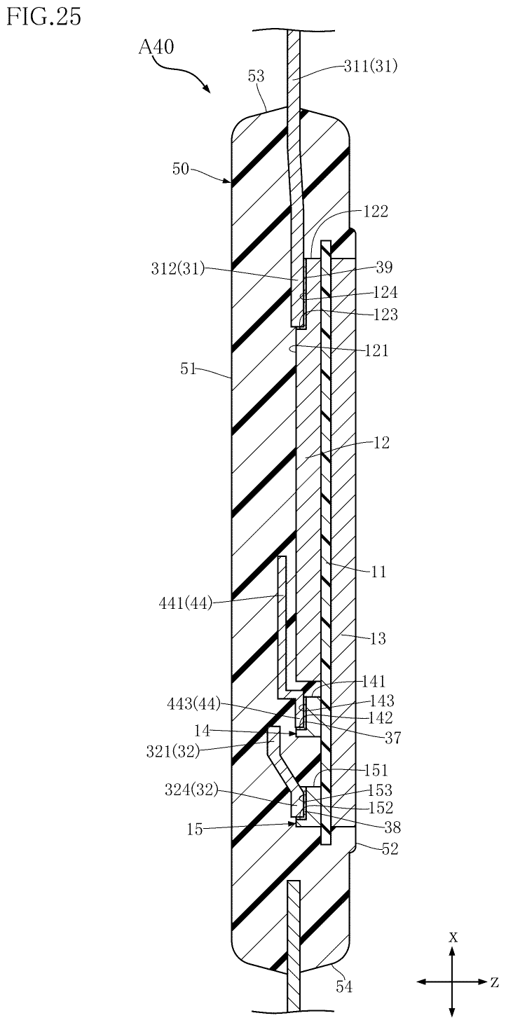

With reference to FIGS. 24 and 25, the following describes a semiconductor device A40 according to a fourth embodiment of the present disclosure. In these figures, elements that are identical or similar to those of the semiconductor device A10 described above are denoted by the same reference numerals, and redundant descriptions are omitted. For convenience, FIG. 24 shows the scaling resin 50 as transparent. The outline of the sealing resin 50 is indicated by imaginary lines in FIG. 24.

Compared with the semiconductor device A30, the semiconductor device A40 includes a conductive member 44 instead of the first conductive member 41 and the second conductive member 42, additionally include a first bonding layer 37, and differs in the configuration of the first wiring layer 14. The conductive member 44, the first bonding layer 37, and the first wiring layer 14 of the semiconductor device A40 are similar in configuration to those of the semiconductor device A20. The description of the conductive member 44, the first bonding layer 37, and the first wiring layer 14 is thus omitted.

As shown in FIG. 24, the second connecting portion 443 of the conductive member 44 and the supporting portion 324 of the second terminal 32 both overlap with an imaginary straight line VL running in the second direction x as viewed in the first direction z.

The following describes advantages of the semiconductor device A40.

The semiconductor device A40 includes a conductive layer 12, a first semiconductor element 21, a second semiconductor element 22, and a first signal terminal 33. The first semiconductor element 21 includes a first gate electrode 213. The second semiconductor element 22 includes a second gate electrode 223. Here, let L1 denote a first straight-line length connecting a first center C1 of the first gate electrode 213 and a first contact point Ca of the first signal terminal 33, and L2 denote a second straight-line length connecting a second center C2 of the second gate electrode 223 and the first contact point Ca. Also, let R1 denote a first conductive-path length from the first center C1 to the first contact point Ca, and R2 denote a second conductive-path length from the second center C2 to the first contact point Ca. When the ratio of the second straight-line length L2 to the first straight-line length L1 and the ratio of the second conductive-path length R2 to the first conductive-path length R1 are compared, the semiconductor device A40 satisfies that R2/R1 is closer to 1 than L2/L1 is (see FIG. 24). The semiconductor device A40 of this configuration is therefore enabled to prevent or reduce resonance phenomena that occur when the plurality of semiconductor elements operate in parallel. Additionally, the semiconductor device A40 has a configuration in common with the semiconductor device A10, thereby achieving the same effect as the semiconductor device A10.

The semiconductor device A40 additionally includes a second signal terminal 34. The first semiconductor element 21 includes a first electrode 211 electrically bonded to the conductive layer 12 and a second electrode 212 electrically connected to the second signal terminal 34. The second semiconductor element 22 includes a third electrode 221 electrically bonded to the conductive layer 12 and a fourth electrode 222 electrically connected to the second signal terminal 34. Here, let L3 denote a third straight-line length connecting a third center C3 of the second electrode 212 and a second contact point Cb of the second signal terminal 34, and L4 denote a fourth straight-line length connecting a fourth center C4 of the fourth electrode 222 and the second contact point Cb. Also, let R3 denote a third conductive-path length from the third center C3 to the second contact point Cb, and R4 denote a fourth conductive-path length from the fourth center C4 to the second contact point Cb. When the ratio of the fourth straight-line length L4 to the third straight-line length L3 and the ratio of the fourth conductive-path length R4 to the third conductive-path length R3 are compared, the semiconductor device A40 satisfies that R4/R3 is closer to 1 than L4/L3 is (see FIG. 24). The semiconductor device A40 of this configuration is therefore enabled to prevent or reduce resonance phenomena that occur when the plurality of semiconductor elements operate in parallel.

The present disclosure is not limited to the embodiments described above. Various modifications in design may be made freely in the specific structure of the present disclosure.

The present disclosure includes embodiments described in the following clauses.

### Clause 1.

A semiconductor device comprising:
a conductive layer including a mounting surface facing in a first direction;
a first semiconductor element including a first gate electrode on a side facing away from the mounting surface in the first direction and bonded to the mounting surface;
a second semiconductor element including a second gate electrode on a side facing away from the mounting surface in the first direction and bonded to the mounting surface;
a first signal terminal electrically connected to each of the first gate electrode and the second gate electrode,
wherein the first gate electrode has a first center as viewed in the first direction,
the second gate electrode has a second center as viewed in the first direction,
the first signal terminal has a first contact point as viewed in the first direction,
L1 denotes a first straight-line length connecting the first center and the first contact point,
L2 denotes a second straight-line length connecting the second center and the first contact point,
R1 denotes a first conductive-path length from the first center to the first contact point, R2 denotes a second conductive-path length from the second center to the first contact point, and
R2/R1 is closer to 1 than is L2/L1.

### Clause 2.

The semiconductor device according to Clause 1, further comprising a first wiring layer,
wherein the first gate electrode, the second gate electrode, and the first signal terminal are each electrically connected to the first wiring layer.

### Clause 3.

The semiconductor device according to Clause 2, further comprising:
a first conductive member electrically bonded to the first gate electrode and the first wiring layer; and
a second conductive member electrically bonded to the second gate electrode and the first wiring layer,
wherein a length of the second conductive member is equal to a length of the first conductive member.

### Clause 4.

The semiconductor device according to Clause 3, wherein the first conductive member and the second conductive member are each a wire.

### Clause 5.

The semiconductor device according to Clause 2, further comprising:
a conductive member electrically bonded to the first gate electrode, the second gate electrode, and the first wiring layer; and
a bonding layer that electrically bonds the first wiring layer and the conductive member.

### Clause 6.

The semiconductor device according to Clause 5, wherein the first wiring layer includes an end surface facing in a direction perpendicular to the first direction, and a peripheral surface facing in a direction perpendicular to the first direction and located inward of the first wiring layer from the end surface as viewed in the first direction,
the first wiring layer includes an engagement portion defined by the peripheral surface,
the conductive member includes a connecting portion electrically bonded to the engagement portion via the bonding layer,
the bonding layer is in contact with the peripheral surface, and
at least a portion of the connecting portion is accommodated in the engagement portion.

### Clause 7.

The semiconductor device according to Clause 2, wherein the first semiconductor element includes a first electrode and a second electrode that are located on opposite sides from each other in the first direction,
the second semiconductor element includes a third electrode and a fourth electrode that are located on opposite sides from each other in the first direction, and
the first electrode and the third electrode are each electrically bonded to the mounting surface.

### Clause 8.

The semiconductor device according to Clause 7, further comprising:
a first terminal electrically connected to the conductive layer; and
a second terminal electrically bonded to each of the second electrode and the fourth electrode.

### Clause 9.

The semiconductor device according to Clause 8, further comprising a second signal terminal that is electrically connected to each of the second electrode and the fourth electrode,
wherein the second electrode has a third center as viewed in the first direction,
the fourth electrode has a fourth center as viewed in the first direction,
the second signal terminal has a second contact point as viewed in the first direction,
L3 denotes a third straight-line length connecting the third center and the second contact point,
L4 denotes a fourth straight-line length connecting the fourth center and the second contact point,
R3 denotes a third conductive-path length from the third center to the second contact point,
R4 denotes a fourth conductive-path length from the fourth center to the second contact point, and
R4/R3 is closer to 1 than is LA/L3.

### Clause 10.

The semiconductor device according to Clause 9, further comprising a second wiring layer,
wherein the second terminal and the second signal terminal are each electrically connected to the second wiring layer.

### Clause 11.

The semiconductor device according to Clause 10, further comprising a bonding layer that electrically bonds the second wiring layer and the second terminal,
wherein the second terminal includes a first bonding portion electrically bonded to the second electrode, a second bonding portion electrically bonded to the fourth electrode, and a supporting portion electrically bonded to the second wiring layer via the bonding layer, and
the supporting portion is located between the first bonding portion and the second bonding portion in a direction perpendicular to the first direction.

### Clause 12.

The semiconductor device according to Clause 11, wherein the second wiring layer includes an end surface facing in a direction perpendicular to the first direction, and a peripheral surface facing in a direction perpendicular to the first direction and located inward of the second wiring layer from the end surface as viewed in the first direction,
the second wiring layer includes an engagement portion defined by the peripheral surface,
the supporting portion is electrically bonded to the engagement portion via the bonding layer,
the bonding layer is in contact with the peripheral surface, and
at least a portion of the supporting portion is accommodated in the engagement portion.

### Clause 13.

The semiconductor device according to any one of Clauses 2 to 12, further comprising a sealing resin covering the first semiconductor element and the second semiconductor element,
wherein the first signal terminal includes a portion exposed from the sealing resin.

### Clause 14.

The semiconductor device according to Clause 13, further comprising an insulating layer,
wherein the conductive layer and the first wiring layer are bonded to a side of the insulating layer facing a side that the mounting surface faces in the first direction, and
the conductive layer and the first wiring layer are each spaced apart from a periphery of the insulating layer as viewed in the first direction.

### Clause 15.

The semiconductor device according to Clause 14, further comprising a heat dissipation layer located on an opposite side of the insulating layer from the conductive layer and bonded to the insulating layer,
wherein the heat dissipation layer is spaced apart from the periphery of the insulating layer as viewed in the first direction,
the insulating layer and the conductive layer are covered with the sealing resin, and
the heat dissipation layer is exposed to outside from the sealing resin.

### Clause 16.

The semiconductor device according to Clause 15, wherein a dimension of each of the conductive layer and the heat dissipation layer in the first direction is larger than a dimension of the insulating layer in the first direction.

### Clause 17.

A semiconductor device comprising:
a conductive layer including a mounting surface facing in a first direction;
a first semiconductor element including a first electrode and a second electrode located on opposite sides from each other in the first direction, the first electrode being electrically bonded to the mounting surface;
a second semiconductor element including a third electrode and a fourth electrode located on opposite sides from each other in the first direction, the third electrode being electrically bonded to the mounting surface; and
a signal terminal electrically connected to each of the second electrode and the fourth electrode,
wherein the second electrode has a first center as viewed in the first direction,
the fourth electrode has a second center as viewed in the first direction,
the signal terminal has a contact point as viewed in the first direction,
L1 denotes a first straight-line length connecting the first center and the contact point,
L2 denotes a second straight-line length connecting the second center and the contact point,
R1 denotes a first conductive-path length from the first center to the contact point,
R2 denotes a second conductive-path length from the second center to the contact point, and
R2/R1 is closer to 1 than is L2/L1.

### Clause 18.

The semiconductor device according to Clause 17, further comprising:
a wiring layer;
a terminal electrically bonded to each of the second electrode, the fourth electrode, and the wiring layer; and
a bonding layer that electrically bonds the wiring layer and the terminal,
wherein the signal terminal is electrically connected to the wiring layer,
the terminal includes a first bonding portion electrically bonded to the second electrode, a second bonding portion electrically bonded to the fourth electrode, and a supporting portion electrically bonded to the wiring layer via the bonding layer, and
the supporting portion is located between the first bonding portion and the second bonding portion in a direction perpendicular to the first direction.

### Clause 19.

The semiconductor device according to Clause 18, wherein the wiring layer includes an end surface facing in a direction perpendicular to the first direction, and a peripheral surface facing in a direction perpendicular to the first direction and located inward of the wiring layer from the end surface as viewed in the first direction,
the wiring layer includes an engagement portion defined by the peripheral surface,
the supporting portion is electrically bonded to the engagement portion via the bonding layer,
the bonding layer is in contact with the peripheral surface, and
at least a portion of the supporting portion is accommodated in the engagement portion.

### Clause 20.

A vehicle comprising:
a drive source; and
a semiconductor device according to Clause 13,
wherein the semiconductor device is electrically connected to the drive source.

REFERENCE NUMERALS

| | |
|---|---|
| A10, A20, A30, A40: semiconductor | 11: insulating layer |
| element | |
| 111: periphery | 12: conductive layer |
| 121: mounting surface | 122: end surface |
| 123: peripheral surface | 123A: upper edge |
| 124: engagement portion | 13: heat dissipation layer |
| 14: first wiring layer | 141: first end surface |
| 142: first peripheral surface | 142A: first upper edge |
| 143: first engagement portion | 15: second wiring layer |
| 151: second end surface | 152: second peripheral surface |
| 152A: second upper edge | 153: second engagement portion |
| 21: first semiconductor element | 211: first electrode |
| 212: second electrode | 213: first gate electrode |
| 22: second semiconductor element | 221: third electrode |
| 222: fourth electrode | 223: second gate electrode |
| 29: conductive bonding layer | 31: first terminal |
| 311: base portion | 312: bonding portion |
| 312A: upper surface | 32: second terminal |
| 321: base portion | 322: first bonding portion |
| 323: second bonding portion | 324: supporting portion |
| 324A: upper surface | 33: first signal terminal |
| 34: second signal terminal | 37: first bonding layer |
| 38: second bonding layer | 39: bonding layer |
| 41: first conductive member | 42: second conductive member |
| 43: third conductive member | 44: conductive member |
| 441: base portion | 442: first connecting portion |
| 443: second connecting portion | 443A: upper surface |
| 50: sealing resin | 51: top surface |
| 52: bottom surface | 53: first side surface |
| 54: second side surface | 81: on-board charger |
| 82: storage battery | 83: drive system |
| 831: inverter | 832: drive source |
| C1 to C4: first to fourth centers | Ca: first contact point |
| Cb: second contact point | L1 to L4: first to fourth |
| | straight-line lengths |
| R1 to R4: first to fourth conductive- | z: first direction |
| path lengths | |
| x: second direction | y: third direction |

1. A semiconductor device comprising:
a conductive layer including a mounting surface facing in a first direction;
a first semiconductor element including a first gate electrode on a side facing away from the mounting surface in the first direction and bonded to the mounting surface;
a second semiconductor element including a second gate electrode on a side facing away from the mounting surface in the first direction and bonded to the mounting surface; and
a first signal terminal electrically connected to each of the first gate electrode and the second gate electrode,
wherein the first gate electrode has a first center as viewed in the first direction,
the second gate electrode has a second center as viewed in the first direction,
the first signal terminal has a first contact point as viewed in the first direction,
L1 denotes a first straight-line length connecting the first center and the first contact point,
L2 denotes a second straight-line length connecting the second center and the first contact point,
R1 denotes a first conductive-path length from the first center to the first contact point,
R2 denotes a second conductive-path length from the second center to the first contact point, and
R2/R1 is closer to 1 than is L2/L1.

2. The semiconductor device according to claim 1, further comprising a first wiring layer,
wherein the first gate electrode, the second gate electrode, and the first signal terminal are each electrically connected to the first wiring layer.

3. The semiconductor device according to claim 2, further comprising:
a first conductive member electrically bonded to the first gate electrode and the first wiring layer; and
a second conductive member electrically bonded to the second gate electrode and the first wiring layer,
wherein a length of the second conductive member is equal to a length of the first conductive member.

4. The semiconductor device according to claim 3, wherein the first conductive member and the second conductive member are each a wire.

5. The semiconductor device according to claim 2, further comprising:
a conductive member electrically bonded to the first gate electrode, the second gate electrode, and the first wiring layer; and
a bonding layer that electrically bonds the first wiring layer and the conductive member.

6. The semiconductor device according to claim 5, wherein the first wiring layer includes an end surface facing in a direction perpendicular to the first direction, and a peripheral surface facing in a direction perpendicular to the first direction and located inward of the first wiring layer from the end surface as viewed in the first direction,
the first wiring layer includes an engagement portion defined by the peripheral surface,
the conductive member includes a connecting portion electrically bonded to the engagement portion via the bonding layer,
the bonding layer is in contact with the peripheral surface, and
at least a portion of the connecting portion is accommodated in the engagement portion.

7. The semiconductor device according to claim 2, wherein the first semiconductor element includes a first electrode and a second electrode that are located on opposite sides from each other in the first direction,
the second semiconductor element includes a third electrode and a fourth electrode that are located on opposite sides from each other in the first direction, and
the first electrode and the third electrode are each electrically bonded to the mounting surface.

8. The semiconductor device according to claim 7, further comprising:
a first terminal electrically connected to the conductive layer; and
a second terminal electrically bonded to each of the second electrode and the fourth electrode.

9. The semiconductor device according to claim 8, further comprising a second signal terminal that is electrically connected to each of the second electrode and the fourth electrode,
wherein the second electrode has a third center as viewed in the first direction,
the fourth electrode has a fourth center as viewed in the first direction,
the second signal terminal has a second contact point as viewed in the first direction,
L3 denotes a third straight-line length connecting the third center and the second contact point,
L4 denotes a fourth straight-line length connecting the fourth center and the second contact point,
R3 denotes a third conductive-path length from the third center to the second contact point, and
R4 denotes a fourth conductive-path length from the fourth center to the second contact point, and
R4/R3 is closer to 1 than is LA/L3.

10. The semiconductor device according to claim 9, further comprising a second wiring layer,
wherein the second terminal and the second signal terminal are each electrically connected to the second wiring layer.

11. The semiconductor device according to claim 10, further comprising a bonding layer that electrically bonds the second wiring layer and the second terminal,
wherein the second terminal includes a first bonding portion electrically bonded to the second electrode, a second bonding portion electrically bonded to the fourth electrode, and a supporting portion electrically bonded to the second wiring layer via the bonding layer, and
the supporting portion is located between the first bonding portion and the second bonding portion in a direction perpendicular to the first direction.

12. The semiconductor device according to claim 11, wherein the second wiring layer includes an end surface facing in a direction perpendicular to the first direction, and a peripheral surface facing in a direction perpendicular to the first direction and located inward of the second wiring layer from the end surface as viewed in the first direction,
the second wiring layer includes an engagement portion defined by the peripheral surface,
the supporting portion is electrically bonded to the engagement portion via the bonding layer,
the bonding layer is in contact with the peripheral surface, and
at least a portion of the supporting portion is accommodated in the engagement portion.

13. The semiconductor device according to claim 2, further comprising a sealing resin covering the first semiconductor element and the second semiconductor element,
wherein the first signal terminal includes a portion exposed from the sealing resin.

14. The semiconductor device according to claim 13, further comprising an insulating layer,
wherein the conductive layer and the first wiring layer are bonded to a side of the insulating layer facing a side that the mounting surface faces in the first direction, and
the conductive layer and the first wiring layer are each spaced apart from a periphery of the insulating layer as viewed in the first direction.

15. The semiconductor device according to claim 14, further comprising a heat dissipation layer located on an opposite side of the insulating layer from the conductive layer and bonded to the insulating layer,
wherein the heat dissipation layer is spaced apart from the periphery of the insulating layer as viewed in the first direction,
the insulating layer and the conductive layer are covered with the sealing resin, and
the heat dissipation layer is exposed to outside from the sealing resin.

16. The semiconductor device according to claim 15, wherein a dimension of each of the conductive layer and the heat dissipation layer in the first direction is larger than a dimension of the insulating layer in the first direction.

17. A semiconductor device comprising:
a conductive layer including a mounting surface facing in a first direction;
a first semiconductor element including a first electrode and a second electrode located on opposite sides from each other in the first direction, the first electrode being electrically bonded to the mounting surface;
a second semiconductor element including a third electrode and a fourth electrode located on opposite sides from each other in the first direction, the third electrode being electrically bonded to the mounting surface; and
a signal terminal electrically connected to each of the second electrode and the fourth electrode,
wherein the second electrode has a first center as viewed in the first direction,
the fourth electrode has a second center as viewed in the first direction,
the signal terminal has a contact point as viewed in the first direction,
L1 denotes a first straight-line length connecting the first center and the contact point,
L2 denotes a second straight-line length connecting the second center and the contact point,
R1 denotes a first conductive-path length from the first center to the contact point,
R2 denotes a second conductive-path length from the second center to the contact point, and
R2/R1 is closer to 1 than is L2/L1.

18. The semiconductor device according to claim 17, further comprising:
a wiring layer;
a terminal electrically bonded to each of the second electrode, the fourth electrode, and the wiring layer; and
a bonding layer that electrically bonds the wiring layer and the terminal,
wherein the signal terminal is electrically connected to the wiring layer,
the terminal includes a first bonding portion electrically bonded to the second electrode, a second bonding portion electrically bonded to the fourth electrode, and a supporting portion electrically bonded to the wiring layer via the bonding layer, and
the supporting portion is located between the first bonding portion and the second bonding portion in a direction perpendicular to the first direction.

19. The semiconductor device according to claim 18, wherein the wiring layer includes an end surface facing in a direction perpendicular to the first direction, and a peripheral surface facing in a direction perpendicular to the first direction and located inward of the wiring layer from the end surface as viewed in the first direction,
the wiring layer includes an engagement portion defined by the peripheral surface,
the supporting portion is electrically bonded to the engagement portion via the bonding layer,
the bonding layer is in contact with the peripheral surface, and
at least a portion of the supporting portion is accommodated in the engagement portion.

20. A vehicle comprising:
a drive source; and
a semiconductor device according to claim 13,
wherein the semiconductor device is electrically connected to the drive source.
